(19) United States
(12) Patent Application Publication
(10) Pub. No.: US 2025/0280691 A1
(43) Pub. Date: Sep. 4, 2025

(54) DISPLAY DEVICE

(71) Applicant: LG Display Co., Ltd., Seoul (KR)

(72) Inventors: Boa JIN, Seoul (KR); Youngchul SHIN, Daegu (KR); KyungMi KIM, Daegu (KR)

(21) Appl. No.: 18/883,898

(22) Filed: Sep. 12, 2024

(30) Foreign Application Priority Data
Feb. 29, 2024 (KR) 10-2024-0030320

(51) Int. Cl. H10K 59/35; H10K 59/90

(52) U.S. Cl. CPC H10K 59/353; H10K 59/351; H10K 59/90

(57) ABSTRACT

Provided is a display device. The display device includes a display panel comprising a display area including a plurality of subpixels, and a non-display area configured to surround the display area, the display area comprising a first optical area including a first transmissive area, a second optical area including a second transmissive area, and a normal area including a light-emitting area; a first optical device disposed below the display panel and configured to overlap with the first optical area; and a second optical device disposed below the display panel and configured to overlap with the second optical area. The display panel is disposed in at least a partial area in the display area and comprises an infrared ray subpixel including an infrared ray-emitting layer.

### CROSS-REFERENCE TO RELATED APPLICATIONS

This application claims the priority of Korean Patent Application No. 10-2024-0030320 filed on Feb. 29, 2024, in the Korean Intellectual Property Office, the disclosure of which is incorporated herein by reference.

### BACKGROUND

### Technical Field

The present specification relates to a display device, and more particularly, to a display device including an infrared sensor.

### Description of the Related Art

Display devices, which visually display electrical information signals, are being rapidly developed. Various studies are being continuously conducted to develop a variety of display devices which are thin and lightweight, consume low power, and have improved performance.

As the representative display devices, there may be a liquid crystal display device (LCD), a field emission display device (FED), an electrowetting display device (EWD), an organic light-emitting display device (OLED), and the like.

An organic electroluminescent display device, as the representative organic light-emitting display device, refers to an organic display device that autonomously emits light. Unlike a liquid-crystal organic light-emitting display device, the electroluminescent display device does not require a separate light source and thus may be manufactured as a lightweight, thin display device. In addition, the organic electroluminescent display device is advantageous in terms of power consumption because the organic electroluminescent display device operates at a low voltage. Further, the organic electroluminescent display device is expected to be adopted in various fields because the organic electroluminescent display device is also excellent in implementation of colors, response speeds, viewing angles, and contrast ratios (CRs).

Recently, multimedia functions of mobile terminals have been improved. For example, an organic light-emitting display device basically equipped with an electronic optical device, such as a camera or sensor, embedded in a front surface of the organic light-emitting display device has been developed. However, the camera or sensor disposed on the front surface of the organic light-emitting display device may restrict a screen design. The organic light-emitting display device adopts a design including a notch or punch hole to reduce a space occupied by the camera or sensor disposed on the front surface of the organic light-emitting display device. However, a screen size is still restricted, which makes it difficult to implement a full-screen display.

In order to implement the full-screen display, there has been proposed a configuration in which an area, in which low-resolution pixels are disposed, is provided in a screen of an organic light-emitting display device, and a camera and/or various types of sensors are disposed in the area in which the low-resolution pixels are disposed.

### BRIEF SUMMARY

The present specification provides a display device in which resolution is improved in a transmissive area in which an electronic optical device, such as a camera or sensor, is disposed in a display area.

The present specification provides a display device in which a size of a hole area in which an electronic optical device, such as a camera or sensor, is disposed in a display area is reduced.

Technical features and characteristics of the present disclosure are not limited to those above-mentioned, and other features and characteristics, which are not mentioned above, can be clearly understood by those skilled in the art from the following descriptions.

A display device according to an embodiment of the present disclosure includes: a display panel including a display area including a plurality of subpixels, and a non-display area configured to surround the display area, the display area including a first optical area including a first transmissive area, a second optical area including a second transmissive area, and a normal area including a light-emitting area; a first optical device disposed below the display panel and configured to overlap with the first optical area; and a second optical device disposed below the display panel and configured to overlap with the second optical area, in which the display panel is disposed in at least a partial area in the display area and includes an infrared ray subpixel including an infrared ray-emitting layer.

Other detailed matters of the exemplary embodiments are included in the detailed description and the drawings.

According to the present specification, a transmitter of the infrared sensor disposed in the display area is excluded, such that a size of the transmissive area or the hole area in which the infrared sensor is disposed is reduced, which may improve resolution of the display device.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIGS. 1A and 1B are schematic top plan views of a display device according to an embodiment of the present specification;

FIG. 2 is a system configuration view of the display device according to the embodiment of the present specification;

FIG. 3 is an equivalent circuit diagram of a subpixel of a display panel according to the embodiment of the present specification;

FIG. 4 is a view illustrating an example in which the subpixels are disposed in a display area of the display panel according to the embodiment of the present specification;

FIG. 5A is a view illustrating an example in which signal lines are disposed in a first optical area and a normal area in the display panel according to the embodiment of the present specification;

FIG. 5B is a view illustrating an example in which signal lines are disposed in a second optical area and the normal area in the display panel according to the embodiment of the present specification;

FIG. 6 is a view illustrating a cross-sectional structure of one subpixel disposed in the normal area and an infrared ray-emitting area in the display panel according to the embodiment of the present specification;

FIG. 7A is a schematic cross-sectional view for explaining light-emitting elements of a plurality of subpixels disposed in the normal area in the display panel according to the embodiment of the present specification;

FIG. 7B is a schematic cross-sectional view for explaining light-emitting elements of a plurality of subpixels disposed in the infrared ray-emitting area in the display panel according to the embodiment of the present specification;

FIG. 8A is a schematic cross-sectional view for explaining light-emitting elements of a plurality of subpixels disposed in a normal area in a display panel according to another embodiment of the present specification;

FIG. 8B is a schematic cross-sectional view for explaining light-emitting elements of a plurality of subpixels disposed in an infrared ray-emitting area in the display panel according to another embodiment of the present specification;

FIG. 9 is a view illustrating cross-sectional structures of light-emitting areas and transmissive areas of the first optical area and the second optical area in the display panel according to the embodiment of the present specification;

FIG. 10 is a schematic top plan view illustrating an example in which subpixels are disposed in a display area of a display device according to another embodiment of the present specification;

FIG. 11A is a schematic cross-sectional view for explaining a first embodiment of light-emitting elements of a plurality of subpixels disposed in an infrared ray-emitting area in a display device according to another embodiment of the present specification;

FIG. 11B is a schematic cross-sectional view for explaining a second embodiment of the light-emitting elements of the plurality of subpixels disposed in the infrared ray-emitting area in the display device according to another embodiment of the present specification;

FIG. 11C is a schematic cross-sectional view for explaining a third embodiment of the light-emitting elements of the plurality of subpixels disposed in the infrared ray-emitting area in the display device according to another embodiment of the present specification;

FIG. 11D is a schematic cross-sectional view for explaining a fourth embodiment of the light-emitting elements of the plurality of subpixels disposed in the infrared ray-emitting area in the display device according to another embodiment of the present specification;

FIG. 12 is a schematic top plan view illustrating an example in which subpixels are disposed in a display area of a display device according to still another embodiment of the present specification;

FIG. 13 is a schematic top plan view of a display device according to yet another embodiment of the present specification; and

FIG. 14 is a schematic top plan view for explaining a second optical area of a display device according to still yet another embodiment of the present specification.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

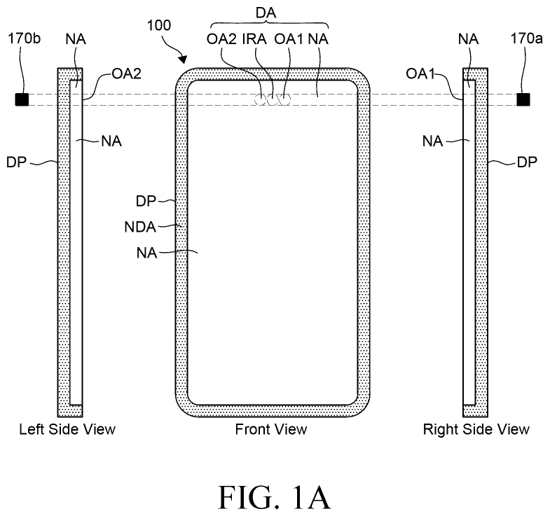

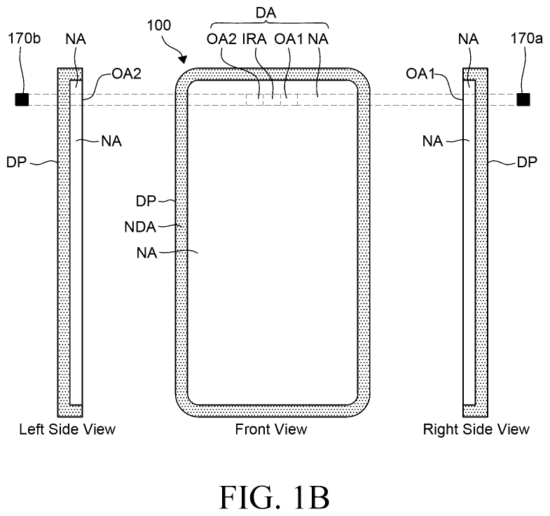

FIGS. 1A and 1B are schematic top plan views of a display device according to an embodiment of the present specification.

With reference to FIGS. 1A and 1B, a display device 100 according to an embodiment of the present specification may include a display panel DP configured to display images, and electronic optical devices 170a and 170b. The electronic optical devices 170a and 170b may each include a light-receiving device, such as a camera or sensor, that receives light.

The display panel DP is a panel configured to display images to a user.

The display panel DP may include a display element configured to display images, a driving element configured to operate the display element, and lines configured to transmit various types of signals to the display element and the driving element. Different display elements may be defined depending on the types of display panels DP. For example, in a case in which the display panel DP is an organic light-emitting display panel, the display element may be an organic light-emitting element including an anode, a light-emitting layer, and a cathode. In addition, the display device 100 according to the embodiment of the present specification may be an organic light-emitting display device.

Meanwhile, the display panel DP may include a substrate, and a plurality of insulation films, transistor layers, and light-emitting element layers disposed on the substrate. To display images, the display panel DP may include a plurality of subpixels, and various types of signal lines configured to operate the plurality of subpixels. The signal lines may include a plurality of data lines, a plurality of gate lines, a plurality of power lines, and the like. In this case, the plurality of subpixels may each include a transistor positioned on a transistor layer, and a light-emitting element positioned on a light-emitting element layer.

The display panel DP may include the display area DA in which images are displayed, and the non-display area NDA in which no image is displayed.

The display area DA may include the plurality of subpixels constituting a plurality of pixels, and a circuit configured to operate the plurality of subpixels. The plurality of subpixels is minimum units constituting the display area DA. The display element may be disposed in each of the plurality of subpixels. The plurality of subpixels may constitute the pixel. For example, the plurality of subpixels may each include an organic light-emitting element including an anode, a light-emitting layer, and a cathode. However, the present specification is not limited thereto. In addition, the circuit configured to operate the plurality of subpixels may include driving elements, lines, and the like. For example, the circuit may include a thin-film transistor, a storage capacitor, a gate line, a data line, and the like. However, the present specification is not limited thereto.

The non-display area NDA may be bent, such that the non-display area NDA is not visible from a front surface. The non-display area NDA may be covered by a casing (not illustrated). The non-display area NDA is called a bezel area.

Various lines and circuits for operating the organic light-emitting element in the display area DA may be disposed in the non-display area NDA. For example, the non-display area NDA may include link lines for transmitting signals to the plurality of sub-pixels and the circuit in the display area DA. The non-display area NDA may include gate-in-panel (GIP) lines or drive ICs such as gate driver ICs and data driver ICs. However, the present specification is not limited thereto.

FIGS. 1A and 1B illustrate that the non-display area NDA surrounds the display area DA having a quadrangular shape. However, the shapes and arrangements of the display area DA and the non-display area NDA are not limited to the example illustrated in FIGS. 1A and 1B. That is, the display area DA and the non-display area NDA may be suitable for the design of an electronic device equipped with the display device 100. For example, an exemplary shape of the display area DA may also be a pentagonal shape, a hexagonal shape, a circular shape, an elliptical shape, or the like.

The display device 100 may further include various additional elements configured to generate various signals or operate a pixel in the display area DA. The additional elements for operating the pixel may include an inverter circuit, a multiplexer, an electrostatic discharge (ESD) circuit, and the like. The display device 100 may also include additional elements related to functions other than the function of operating the pixel. For example, the display device 100 may further include additional elements that provide a touch detection function, a user certification function (e.g., fingerprint recognition), a multi-level pressure detection function, a tactile feedback function, and the like. The above-mentioned additional elements may be positioned in the non-display area NDA and/or an external circuit connected to a connection interface.

With reference to FIGS. 1A and 1B, in the display device 100 according to the embodiments of the present specification, the one or more electronic optical devices 170a and 170b may be electronic components positioned at a lower side of the display panel DP (a side opposite to a visual surface).

The light may enter the front surface (visual surface) of the display panel DP, passes through the display panel DP, and then propagate to the one or more electronic optical devices 170a and 170b positioned at the lower side (the side opposite to the visual surface) of the display panel DP.

The one or more electronic optical devices 170a and 170b may be devices that receive the light having passed through the display panel DP and perform predetermined functions in response to the received light. For example, the electronic optical devices 170a and 170b may include any one or more of an image capturing device, such as a camera (image sensor), and a detection sensor, such as a proximity sensor and an illuminance sensor.

With reference to FIGS. 1A and 1B, in the display device 100 according to the embodiments of the present specification, the display area DA may include a first display area including a first optical area OA1 and a second optical area OA2, a normal area NA, and a second display area that is an infrared ray-emitting area IRA. More specifically, the display area DA may include the first optical area, the second optical area, the normal area NA, and the infrared ray-emitting area IRA.

The first optical area OA1 and the second optical area OA2 may each be an area that overlaps the one or more electronic optical devices.

FIG. 1A illustrates a structure in which the first optical area OA1 and the second optical area OA2 each have a circular shape. However, the shapes of the first optical area OA1 and the second optical area OA2 according to the embodiment of the present specification are not limited thereto. For example, the first optical area OA1 and the second optical area OA2 may each have an octagonal shape or various polygonal shapes.

According to the example in FIG. 1A, the display area DA may include the normal area NA, the infrared ray-emitting area IRA, the first optical area OA1, and the second optical area OA2. In the example in FIG. 1A, the normal area NA and the infrared ray-emitting area IRA may be present between the first optical area OA1 and the second optical area OA2. In this case, at least a part of the first optical area OA1 may overlap with the first electronic optical device 170a, and at least a part of the second optical area OA2 may overlap with the second electronic optical device 170b.

In the example in FIG. 1B, the normal area NA is not present between the first optical area OA1 and the second optical area OA2. That is, the first optical area OA1 and the second optical area OA2 may adjoin each other. In this case, the infrared ray-emitting area IRA may be positioned adjacent to the first optical area OA1 or the second optical area OA2. In this case, at least a part of the first optical area OA1 may overlap with the first electronic optical device 170a, and at least a part of the second optical area OA2 may overlap with the second electronic optical device 170b.

The first optical area OA1 and the second optical area OA2 each have both an image display structure and a light transmission structure. That is, because the first optical area OA1 and the second optical area OA2 are partial areas of the display area DA, the pixels for displaying images need to be disposed in the first optical area OA1 and the second optical area OA2, and the light transmission structure for transmitting light to the electronic optical devices 170a and 170b needs to be provided.

The electronic optical devices 170a and 170b are light-receiving devices. For example, the electronic optical devices 170a and 170b may each be an image capturing device, such as a camera, and a detection sensor, such as a proximity sensor and an illuminance sensor. The electronic optical devices 170a and 170b are positioned at a rear side (or the lower side, i.e., the side opposite to the visual surface) of the display panel DP and receive the light having passed through the display panel DP. In this case, the one or more electronic optical devices 170a and 170b are not exposed to the front surface (visual surface) of the display panel DP. Therefore, the user does not visually recognize the electronic optical devices 170a and 170b when the user looks at the front surface of the display device 100.

More specifically, the first electronic optical device 170a may be a camera, and the second electronic optical device 170b may be an infrared detection sensor such as a proximity sensor or an illuminance sensor. In this case, the second electronic optical device 170b may be an infrared receiving device configured to detect infrared rays applied from the outside, and a separate infrared transmitting device may not be included. On the contrary, the first electronic optical device 170a may be a detection sensor, and the second electronic optical device 170b may be a camera. Hereinafter, for convenience of description, an example will be described in which the first electronic optical device 170a is a camera, and the second electronic optical device 170b is an infrared detection sensor. In this case, the camera may be a camera lens or an image sensor.

In case that the first electronic optical device 170a is a camera, the camera may be positioned at the rear side (or the lower side) of the display panel DP. However, the camera may be the front surface camera configured to capture an image of an object disposed forward of the display panel DP. Therefore, the user may capture an image by using the camera, which is not visible from the visual surface, while looking at the visual surface of the display panel DP.

The normal area NA, the infrared ray-emitting area IRA, the first optical area OA1, and the second optical area OA2 included in the display area DA are areas in which images may be displayed. However, the normal area NA and the infrared ray-emitting area IRA are areas that do not require the light transmission structure, and the first optical area OA1 and the second optical area OA2 are areas that need to have the light transmission structures. Therefore, the first optical area OA1 and the second optical area OA2 each need to have transmittance at a predetermined level or higher. The normal area NA and the infrared ray-emitting area IRA may not have optical transmittance or have low transmittance at less than the predetermined level.

For example, the first optical area OA1, the second optical area OA2, the normal area NA, and the infrared ray-emitting area IRA may be different in resolution, subpixel arrangement structure, number of subpixels per unit area, electrode structure, line structure, electrode arrangement structure, line arrangement structure, or the like.

For example, the number of subpixels per unit area in the first optical area OA1 and the second optical area OA2 may be smaller than the number of subpixels per unit area in the normal area NA and the infrared ray-emitting area IRA. That is, the resolution of the first optical area OA1 and the second optical area OA2 may be lower than the resolution of the normal area NA and the infrared ray-emitting area IRA. In this case, the number of subpixels per unit area may be a criterion for measuring the resolution and may also be referred to as PPI (pixels per inch) that means the number of pixels within 1 inch.

For example, the number of subpixels per unit area in the first optical area OA1 may be smaller than the number of subpixels per unit area in the normal area NA. In addition, the number of subpixels per unit area in the second optical area OA2 may be equal to or larger than the number of subpixels per unit area in the first optical area OA1.

The first optical area OA1 may have various shapes such as a circular shape, an elliptical shape, a quadrangular shape, a hexagonal shape, or an octagonal shape. The second optical area OA2 may have various shapes such as a circular shape, an elliptical shape, a quadrangular shape, a hexagonal shape, or an octagonal shape. The first optical area OA1 and the second optical area OA2 may have the same shape or different shapes.

With reference to FIG. 1B, in case that the first optical area OA1 and the second optical area OA2 adjoin each other, an overall optical area including the first optical area OA1 and the second optical area OA2 may have various shapes such as a circular shape, an elliptical shape, a quadrangular shape, a hexagonal shape, or an octagonal shape.

Hereinafter, for convenience of description, an example will be described in which the first optical area OA1 and the second optical area OA2 each have a circular shape.

In the display device 100 according to the embodiment of the present specification, in case that the first electronic optical device 170a, which is hidden at the lower side of the display panel DP without being exposed to the outside, is a camera, the display device 100 according to the embodiment of the present specification may be a display device to which an under-display camera (UDC) technology is applied.

According to this configuration, in the display device 100 according to the embodiment of the present specification, a notch or camera hole for exposing a camera or detection sensor need not be formed in the display panel DP, such that an area of the display area DA does not decrease. Therefore, because the notch or camera hole for exposing the camera or detection sensor need not be formed in the display panel DP, a size of a bezel area may decrease, and a design constraint may be eliminated, such that a degree of freedom may increase.

In the display device 100 according to the embodiment of the present specification, even though the electronic optical devices 170a and 170b are positioned to be hidden at the rear side of the display panel DP, the electronic optical devices 170a and 170b need to normally receive light and normally perform the predetermined functions.

In addition, in the display device 100 according to the embodiment of the present specification, even though the electronic optical devices 170a and 170b are positioned to be hidden at the rear side of the display panel DP and positioned to overlap with the display area DA, images need to be normally displayed in the first and second optical areas OA1 and OA2 that overlap with the electronic optical devices 170a and 170b in the display area DA.

Therefore, the display device 100 according to the embodiment of the present specification may have a structure capable of improving the transmittance of the first optical area OA1 and the second optical area OA2 that overlap with the electronic optical devices 170a and 170b.

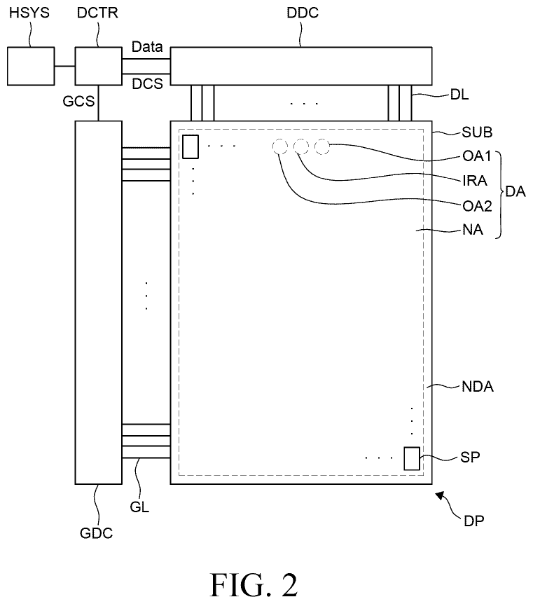

FIG. 2 is a system configuration view of the display device according to the embodiment of the present specification.

With reference to FIG. 2, the display device 100 may include the display panel DP and a display drive circuit that are constituent elements for displaying images. The display drive circuit may be a circuit for operating the display panel DP and include a data drive circuit DDC, a gate drive circuit GDC, and a display controller DCTR.

The display panel DP may include the display area DA in which images are displayed, and the non-display area NDA in which no image is displayed. The non-display area NDA may be an outer peripheral area of the display area DA and also referred to as a bezel area. The entirety or a part of the non-display area NDA may be an area visible from the front surface of the display device 100 or an area that is bent and not visible from the front surface of the display device 100.

The display panel DP may include a substrate SUB, and a plurality of subpixels SP disposed on the substrate SUB. In addition, the display panel DP may further include various types of signal lines to operate the plurality of subpixels SP.

The display device 100 according to the embodiments of the present specification may be an organic spontaneous light-emitting display device in which the display panel DP autonomously emits light. The plurality of subpixels SP may each include the light-emitting element.

For example, the display device 100 according to the embodiments of the present specification may be an organic light-emitting display device in which a light-emitting element is implemented as an organic light-emitting diode (OLED). As another example, the display device 100 according to the embodiments of the present specification may be an inorganic or organic light-emitting display device in which a light-emitting element is implemented as a light-emitting diode made of an inorganic material. As still another example, the display device 100 according to the embodiments of the present specification may be a quantum dot display device implemented by quantum dots, which are semiconductor crystals, so that a light-emitting element autonomously emits light.

The structure of each of the plurality of subpixels SP may vary depending on the type of display device 100. For example, in case that the display device 100 is an organic spontaneous light-emitting display device having the subpixel SP that autonomously emits light, the subpixels SP may each include a light-emitting element configured to autonomously emit light, one or more transistors, and one or more capacitors.

Various types of signal lines may include a plurality of data lines DL configured to transmit data signals (also referred to as data voltages or image signals), and a plurality of gate lines GL configured to transmit gate signals (also referred to as scan signals).

The plurality of data lines DL and the plurality of gate lines GL may intersect one another. The plurality of data lines DL may each be disposed while extending in a first direction. The plurality of gate lines GL may each be disposed while extending in a second direction. In this case, the first direction may be a column direction, and the second direction may be a row direction. Alternatively, the first direction may be a row direction, and the second direction may be a column direction.

The data drive circuit DDC may be a circuit for operating the plurality of data lines DL and output data signals to the plurality of data lines DL. The gate drive circuit GDC may be a circuit for operating the plurality of gate lines GL and output gate signals to the plurality of gate lines GL.

The display controller DCTR may be a device for controlling the data drive circuit DDC and the gate drive circuit GDC and control driving timing for the plurality of data lines DL and driving timing for the plurality of gate lines GL.

The display controller DCTR may supply a data drive control signal DCS to the data drive circuit DDC to control in order to control the data drive circuit DDC and supply a gate drive control signal GCS to the gate drive circuit GDC in order to control the gate drive circuit GDC.

The display controller DCTR may receive input image data from a host system HSYS and supply image data Data to the data drive circuit DDC on the basis of the input image data.

The data drive circuit DDC may supply the data signals to the plurality of data lines DL on the basis of driving timing control of the display controller DCTR. The data drive circuit DDC may receive digital image data Data from the display controller DCTR, convert the received image data Data into analog data signals, and output the analog data signals to the plurality of data lines DL.

The gate drive circuit GDC may supply the gate signals to the plurality of gate lines GL on the basis of timing control of the display controller DCTR. The gate drive circuit GDC may generate gate signals by receiving a first gate voltage, which corresponds to a turn-on level voltage, and a second gate voltage, which corresponds to a turn-off level voltage, together with various types of gate driving control signals GCS and supply the generated gate signals to the plurality of gate lines GL.

The gate drive circuit GDC supplies the gate signal to the gate line GL in response to the gate drive control signal GCS supplied from the display controller DCTR. The gate drive circuit GDC may be disposed at one side or two opposite sides of the display panel in a gate-in-panel (GIP) manner.

The gate drive circuit GDC sequentially outputs the gate signals to the plurality of gate lines GL under the control of the display controller DCTR. The gate drive circuit GDC may shift the gate signals by using a shift register and sequentially supply the signals to the gate lines GL.

In the organic light-emitting display device, the gate signals may include the scan signal SC and the light emission control signal EM. The scan signal SC includes a scan signal pulse that swings between the first gate voltage and the second gate voltage. The light-emitting control signal EM may include a light-emitting control signal pulse that swings between a third gate voltage and a fourth gate voltage.

The scan pulse is synchronized with a data voltage Vdata and selects the subpixels SP on the line to which data is written. The light-emitting control signal EM defines light-emitting time of each of the subpixels SP.

The gate drive circuit GDC may include a light-emitting control signal driver EDC configured to output the light-emitting control signal EM, and one or more scan drivers SDC configured to output the scan signal SC.

The light-emitting control signal driver EDC outputs the light-emitting control signal EM in response to a start pulse and a shift clock from the display controller DCTR and sequentially shifts the light-emitting control signal pulse in response to the shift clock.

The one or more scan drivers SDC output the scan signal SC in response to the start pulse and the shift clock from the display controller DCTR and shift the scan signal pulse in accordance with a shift clock timing.

In the gate drive circuit GDC disposed in the GIP manner, the shift registers may be configured symmetrically at two opposite sides of the display area DA. In addition, the gate drive circuit GDC may be configured such that the shift register at one side of the display area DA includes at least one scan driver SDC and a light-emitting control signal driver 310, and the shift register at the other side of the display area DA includes at least one scan driver SDC. However, the present specification is not limited thereto. The light-emitting control signal driver EDC and the at least one scan driver SDC may be differently disposed according to the embodiment.

The data drive circuit DDC may be connected to the display panel DP in a tape-automated bonding (TAB) manner, connected to a bonding pad of the display panel DP in a chip-on-glass (COG) or chip-on-panel (COP) manner, or connected to the display panel DP in a chip-on-film (COF) manner.

The gate drive circuit GDC may be connected to the display panel DP in a tape-automated bonding (TAB) manner, connected to the bonding pad of the display panel DP in a chip-on-glass (COG) or chip-on-panel (COP) manner, or connected to the display panel DP in a chip-on-film (COF) manner. Alternatively, the gate drive circuit GDC may be formed as a gate1-in-panel (GIP) type in the non-display area NDA of the display panel DP. The gate drive circuit GDC may be disposed on the substrate or connected to the substrate. That is, in case that the gate drive circuit GDC is the GIP type, the gate drive circuit GDC may be disposed in the non-display area NDA of the substrate. In case that the gate drive circuit GDC is a chip-on-glass (COG) type, a chip-on-film (COF) type, or the like, the gate drive circuit GDC may be connected to the substrate.

Meanwhile, at least one of the data drive circuit DDC and the gate drive circuit GDC may be disposed in the display area DA of the display panel DP. For example, at least one of the data drive circuit DDC and the gate drive circuit GDC may be disposed so as not to overlap with the subpixels SP or disposed to overlap with some or all of the subpixels SP.

The data drive circuit DDC may be connected to one side (e.g., upper or lower side) of the display panel DP. Depending on operating methods, panel designing methods, or the like, the data drive circuits DDC may be connected to both the two opposite sides (e.g., upper and lower sides) of the display panel DP or connected to two or more side surfaces among the four side surfaces of the display panel DP.

The gate drive circuit GDC may be connected to one side (e.g., left or right side) of the display panel DP. Depending on operating methods, panel designing methods, or the like, the gate drive circuits GDC may be connected to both the two opposite sides (e.g., left and right sides) of the display panel DP or connected to two or more side surfaces among the four side surfaces of the display panel DP.

The display controller DCTR may be implemented as a component provided separately from the data drive circuit DDC or implemented as an integrated circuit by being integrated with the data drive circuit DDC.

The display controller DCTR may be a timing controller used for a typical display technology or may be a control device including a timing controller and configured to further perform other control functions. Alternatively, the display controller DCTR may be a control device different from a timing controller or may be a circuit disposed in a control device. The display controller DCTR may be implemented as an electronic component or various circuits such as integrated circuits (ICs), field programmable GATE1 arrays (FPGAs), application specific integrated circuits (ASICs), or processors.

The display controller DCTR may be mounted on a printed circuit board, a flexible printed circuit, or the like and electrically connected to the data drive circuit DDC and the gate drive circuit GDC through the printed circuit board, the flexible printed circuit, or the like.

The display controller DCTR may transmit a signal to the data drive circuit DDC and receive a signal from the data drive circuit DDC in accordance with one or more predetermined interfaces. In this case, for example, the interfaces may include a low-voltage differential signaling (LVDS) interface, an embedded clock point-to-point interface (EPI), a serial peripheral interface (SPI), and the like.

To further provide a touch sensing function in addition to the image display function, the display device 100 according to the embodiments of the present specification may include a touch sensor, and a touch sensing circuit configured to sense the touch sensor to detect whether a touch is made by a touch object such as a finger, a pen, or the like or to detect a touch position.

The touch sensing circuit may further include a touch drive circuit configured to operate the touch sensor, sense the touch sensor, and produce and output touch sensing data, and a touch controller configured to use the touch sensing data to detect the occurrence of a touch or a touch position.

The touch sensor may include a plurality of touch electrodes. The touch sensor may further include a plurality of touch lines configured to electrically connect the plurality of touch electrodes and the touch drive circuit.

The touch sensor may be provided in the form of a touch panel disposed outside the display panel DP or provided in the display panel DP. In case that the touch sensor is provided in the form of a touch panel present outside the display panel DP, the touch sensor is called an externally-carried touch sensor. In case that the touch sensor is an externally-carried touch sensor, the touch panel and the display panel DP may be separately manufactured and coupled to each other during an assembling process. The externally-carried touch panel may include a touch panel substrate, and the plurality of touch electrodes disposed on the touch panel substrate.

In case that the touch sensor is present inside the display panel DP, the touch sensor may be provided on the substrate SUB together with signal lines and electrodes related to a display operation during a process of manufacturing the display panel DP.

A touch drive circuit TDC may supply a touch driving signal to at least one of the plurality of touch electrodes, sense at least one of the plurality of touch electrodes, and produce touch sensing data.

The touch sensing circuit may perform touch sensing in a self-capacitance sensing manner or a mutual-capacitance sensing manner.

In case that the touch sensing circuit performs touch sensing in a self-capacitance sensing manner, the touch sensing circuit may perform the touch sensing on the basis of capacitance between each of the touch electrodes and the touch object (e.g., a finger, a pen, or the like).

According to the self-capacitance sensing manner, the plurality of touch electrodes may serve as a drive touch electrode and a sensing touch electrode. The touch drive circuit TDC may operate all or some of the plurality of touch electrodes and sense all or some of the plurality of touch electrodes.

In case that the touch sensing circuit performs touch sensing in a mutual-capacitance sensing manner, the touch sensing circuit may perform the touch sensing on the basis of capacitance between the touch electrodes.

According to the mutual-capacitance sensing manner, the plurality of touch electrodes is classified into drive touch electrodes and sensing touch electrodes. The touch drive circuit may operate the drive touch electrodes and sense the sensing touch electrodes.

The touch drive circuit and the touch controller, which are included in the touch sensing circuit, may be implemented as separate devices or a single device. In addition, the touch drive circuit and the data drive circuit DDC may be implemented as separate devices or a single device.

In addition, the display device 100 may further include a power supply circuit configured to supply various types of power to the display drive circuit and/or the touch sensing circuit.

The display device 100 according to the embodiments of the present specification may be a mobile terminal such as a smartphone or a tablet, or a monitor or a television (TV) having various sizes. However, the present specification is not limited thereto. The display device 100 may be one of the displays having various types and various sizes and being capable of displaying information or images.

As described above, the display area DA of the display panel DP may include the normal area NA, the infrared ray-emitting area IRA, the first optical area OA1, and the second optical area OA2.

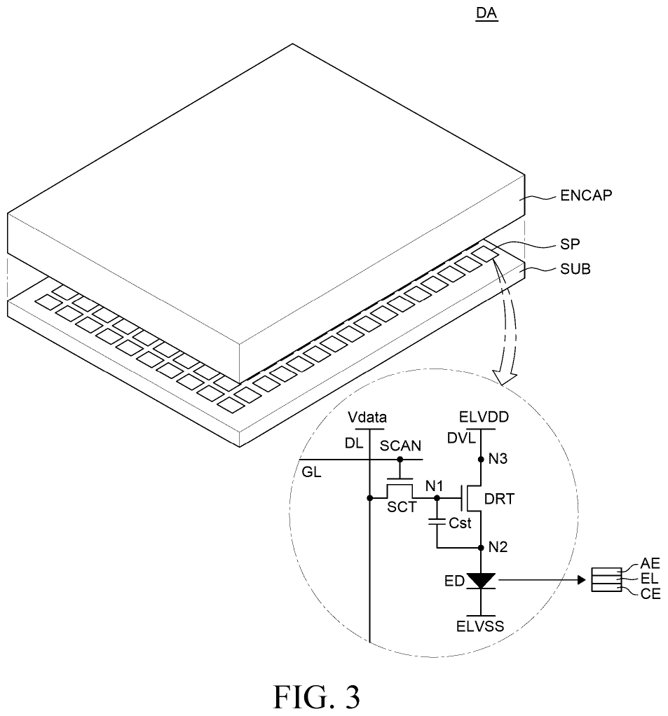

FIG. 3 is an equivalent circuit diagram of a subpixel of a display panel according to the embodiment of the present specification.

The subpixels SP, which are disposed in the normal area NA, the first optical area OA1, and the second optical area OA2 included in the display area DA of the display panel DP, may each include a light-emitting element ED, a driving transistor DRT configured to operate the light-emitting element ED, a scan transistor SCT configured to transmit a data voltage VDATA to a first node N1 of the driving transistor DRT, and a storage capacitor Cst configured to maintain a predetermined voltage for one frame.

The driving transistor DRT may include the first node N1 to which the data voltage may be applied, a second node N2 electrically connected to the light-emitting element ED, and a third node N3 to which a drive voltage ELVDD is applied from a drive voltage line DVL. In the driving transistor DRT, the first node N1 may be a gate node, the second node N2 may be a source node or drain node, and the third node N3 may be a drain node or source node.

The light-emitting element ED may include an anode electrode AE, a light-emitting layer EL, and a cathode electrode CE. The anode electrode AE may be a pixel electrode disposed in each of the subpixels SP and electrically connected to the second node N2 of the driving transistor DRT of the subpixel SP. The cathode electrode CE may be a common electrode disposed in common in the plurality of subpixels SP, and a base voltage ELVSS may be applied to the cathode electrode CE.

For example, the anode electrode AE may be a pixel electrode, and the cathode electrode CE may be a common electrode. On the contrary, the anode electrode AE may be a common electrode, and the cathode electrode CE may be a pixel electrode. Hereinafter, for convenience of description, it is assumed that the anode electrode AE is a pixel electrode, and the cathode electrode CE is a common electrode.

For example, the light-emitting element ED may be an organic light-emitting diode (OLED), an inorganic light-emitting diode, a quantum-dot light-emitting element, or the like. In this case, in case that the light-emitting element ED is an organic light-emitting diode, the light-emitting layer EL of the light-emitting element ED may include an organic light-emitting layer including an organic material.

The scan transistor SCT is turned on or off by being controlled in response to a scan signal SCAN that is a gate signal applied through the gate line GL. The scan transistor SCT may be electrically connected between the first node N1 of the driving transistor DRT and the data line DL.

The storage capacitor Cst may be electrically connected between the first node N1 and the second node N2 of the driving transistor DRT.

As illustrated in FIG. 3, the subpixels SP may each have a 2T (transistor) 1C (capacitor) structure including two transistors DRT and SCT and a single capacitor Cst. In some instances, the subpixel SP may further include one or more transistors or further include one or more capacitors.

The storage capacitor Cst is not a parasitic capacitor (e.g., Cgs or Cgd) that is an internal capacitor that may be present between the first node N1 and the second node N2 of the driving transistor DRT. However, the storage capacitor Cst may be an external capacitor intentionally designed outside the driving transistor DRT.

The driving transistor DRT and the scan transistor SCT may each be an n-type transistor or a p-type transistor.

The circuit element (particularly, the light-emitting element ED) in each of the subpixels SP is vulnerable to outside moisture or oxygen. Therefore, an encapsulation layer ENCAP may be disposed on the display panel DP in order to inhibit outside moisture or oxygen from penetrating into the circuit element (particularly, the light-emitting element ED). The encapsulation layer ENCAP may be disposed in a shape that covers the light-emitting elements ED.

Meanwhile, a differential pixel density designing method may be applied as one method of increasing the transmittance of at least one of the first optical area OA1 and the second optical area OA2. According to the differential pixel density designing method, the display panel DP may be designed so that the number of subpixels per unit area in at least one of the first optical area OA1 and the second optical area OA2 is smaller than the number of subpixels per unit area in the normal area NA.

However, in some instances, alternatively, a differential pixel size designing method may be applied as another method of increasing the transmittance of at least one of the first optical area OA1 and the second optical area OA2. According to the differential pixel size designing method, the display panel DP may be designed so that the number of subpixels per unit area in at least one of the first optical area OA1 and the second optical area OA2 is equal or similar to the number of subpixels per unit area in the normal area NA, and a size (i.e., light-emitting area size) of each of the subpixels SP disposed in at least one of the first optical area OA1 and the second optical area OA2 is smaller than a size (i.e., light-emitting area size) of each of the subpixels SP disposed in the normal area NA.

Hereinafter, for convenience of description, the description will be made on the assumption that the differential pixel density designing method is applied between the two types of methods (the differential pixel density designing method and the differential pixel size designing method) of increasing the transmittance of at least one of the first optical area OA1 and the second optical area OA2.

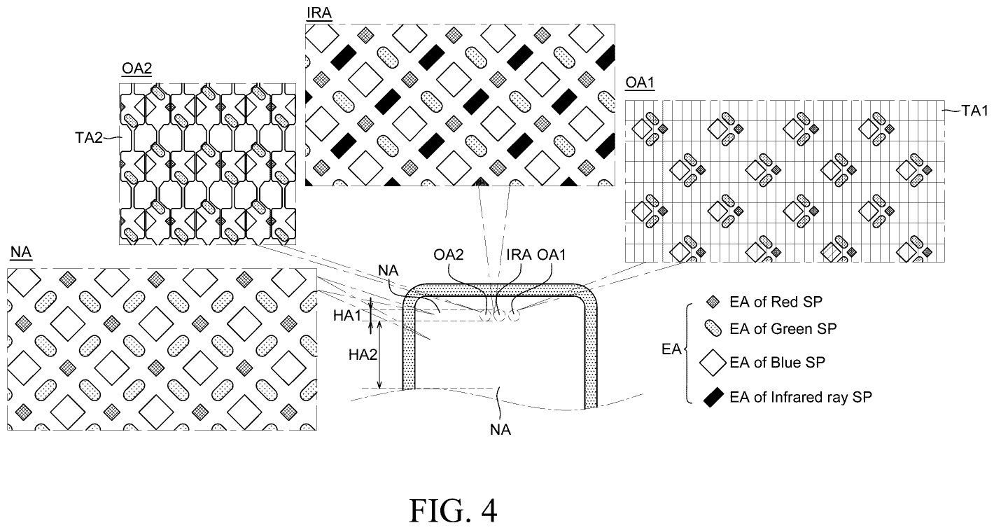

FIG. 4 is a view illustrating an example in which the subpixels are disposed in the display area of the display panel according to the embodiment of the present specification.

FIG. 4 illustrates that the subpixels SP are disposed in the four areas NA, IRA, OA1, and OA2 included in the display area DA.

With reference to FIG. 4, the plurality of subpixels SP may be disposed in the normal area NA, the infrared ray-emitting area IRA, the first optical area OA1, and the second optical area OA2 included in the display area DA.

For example, the plurality of subpixels SP may include a red subpixel Red SP configured to emit red light, a green subpixel Green SP configured to emit green light, and a blue subpixel Blue SP configured to emit blue light.

Therefore, the normal area NA, the infrared ray-emitting area IRA, the first optical area OA1, and the second optical area OA2 may each include a light-emitting area EA for the red subpixel Red SP, a light-emitting area EA for the green subpixel Green SP, and a light-emitting area EA for the blue subpixel Blue SP.

The normal area NA and the infrared ray-emitting area IRA may each include the light-emitting area EA without including the light transmission structure.

With reference to FIG. 4, unlike the first optical area OA1 and the second optical area OA2, the normal area NA includes the light-emitting area EA without including the light transmission structure. In this case, the normal area NA may include a plurality of unit pixels each including the red subpixel Red SP, the green subpixel Green SP, and the blue subpixel Blue SP. For example, in FIG. 4, one red subpixel Red SP, two green subpixels Green SP, and one blue subpixel Blue SP may be included and disposed in one unit pixel. However, the present specification is not limited thereto.

In comparison with the normal area NA, the infrared ray-emitting area IRA further includes an infrared ray subpixel Infrared ray SP capable of emitting infrared rays in addition to the red subpixel Red SP, the green subpixel Green SP, and the blue subpixel Blue SP. The infrared ray subpixel Infrared ray SP is a pixel configured to emit light in a near infrared ray-emitting area with a wavelength of 700 nm to 1100 nm. As described below, the infrared ray subpixel Infrared ray SP may serve as a transmitter of the infrared detection sensor.

With reference to FIG. 4, the infrared ray-emitting area IRA may include the light-emitting area EA of the red subpixel Red SP, the light-emitting area EA of the green subpixel Green SP, the light-emitting area EA of the blue subpixel Blue SP, and the light-emitting area EA of the infrared ray subpixel Infrared ray SP. In this case, the infrared ray-emitting area IRA may include the plurality of unit pixels each including the red subpixel Red SP, the green subpixel Green SP, the blue subpixel Blue SP, and the infrared ray subpixel Infrared ray SP. For example, in FIG. 4, one red subpixel Red SP, one green subpixel Green SP, one blue subpixel Blue SP, and one infrared ray subpixel Infrared ray SP may be included and disposed in one unit pixel. However, the present specification is not limited thereto.

The first optical area OA1 and the second optical area OA2 each include the light transmission structure while including the light-emitting area EA. The first optical area OA1 may include the light-emitting area EA and a first transmissive area TA1, and the second optical area OA2 may include the light-emitting area EA and a second transmissive area TA2.

The light-emitting area EA and the transmissive areas TA1 and TA2 may be distinguished depending on whether light may be transmitted. That is, the light-emitting area EA may be an area that cannot transmit light, and the transmissive areas TA1 and TA2 may be areas that may transmit light.

In addition, the light-emitting area EA and the transmissive areas TA1 and TA2 may be distinguished depending on whether a particular metal layer is formed. For example, a cathode electrode may be formed in the light-emitting area EA, but no cathode electrode may be formed in the transmissive areas TA1 and TA2. In addition, a light-blocking layer may be formed in the light-emitting area EA, but no light-blocking layer may be formed in the transmissive areas TA1 and TA2.

In the transmissive areas TA1 and TA2, an anti-deposition layer (not illustrated) made of an organic material may be disposed on the same plane as the cathode electrode. During a process of forming the cathode electrode, a cathode electrode material is not deposited on the anti-deposition layer, such that the cathode electrode may be selectively formed on the substrate SUB.

The first optical area OA1 includes the first transmissive area TA1, and the second optical area OA2 includes the second transmissive area TA2, such that both the first optical area OA1 and the second optical area OA2 may transmit light.

The transmittance of the first optical area OA1 and the transmittance of the second optical area OA2 may be equal to each other. In this case, the first transmissive area TA1 of the first optical area OA1 and the second transmissive area TA2 of the second optical area OA2 may be identical in shape or size. Alternatively, even though the first transmissive area TA1 of the first optical area OA1 and the second transmissive area TA2 of the second optical area OA2 are different in shape or size, a proportion of the first transmissive area TA1 in the first optical area OA1 and a proportion of the second transmissive area TA2 in the second optical area OA2 may be equal to each other.

Alternatively, the transmittance (degree of light transmission) of the first optical area OA1 and the transmittance (degree of light transmission) of the second optical area OA2 may be different from each other. In this case, the first transmissive area TA1 of the first optical area OA1 and the second transmissive area TA2 of the second optical area OA2 may be different in shape or size. Alternatively, even though the first transmissive area TA1 of the first optical area OA1 and the second transmissive area TA2 of the second optical area OA2 are identical in shape or size, a proportion of the first transmissive area TA1 in the first optical area OA1 and a proportion of the second transmissive area TA2 in the second optical area OA2 may be different from each other.

For example, in case that the first electronic optical device, which overlaps the first optical area OA1, is a camera and the second electronic optical device, which overlaps the second optical area OA2, is an infrared detection sensor, the camera may require a larger light amount than the detection sensor. Therefore, the transmittance of the first optical area OA1 may be higher than the transmittance of the second optical area OA2. In this case, the first transmissive area TA1 of the first optical area OA1 may have a larger size than the second transmissive area TA2 of the second optical area OA2. Alternatively, even though the first transmissive area TA1 of the first optical area OA1 and the second transmissive area TA2 of the second optical area OA2 are identical in size, a proportion of the first transmissive area TA1 in the first optical area OA1 may be larger than a proportion of the second transmissive area TA2 in the second optical area OA2.

Hereinafter, for convenience of description, an example will be described in which the transmittance of the first optical area OA1 is higher than the transmittance of the second optical area OA2.

The transmissive areas TA1 and TA2 illustrated in FIG. 4 may each be referred to as a transparent area, and the transmittance may be referred to as transparency.

In the embodiment of the present specification, as illustrated in FIG. 4, it is assumed that the first optical area OA1 and the second optical area OA2 are positioned at an upper end of the display area of the display panel and disposed side by side in a leftward/rightward direction.

With reference to FIG. 4, a horizontal display area, in which the infrared ray-emitting area IRA, the first optical area OA1, and the second optical area OA2 are disposed, is referred to as a first horizontal display area HA1, and a horizontal display area, in which the first optical area OA1 and the second optical area OA2 are not disposed, is referred to as a second horizontal display area HA2.

The first horizontal display area HA1 may include the normal area NA, the infrared ray-emitting area IRA, the first optical area OA1, and the second optical area OA2. In contrast, the second horizontal display area HA2 may include the normal area NA.

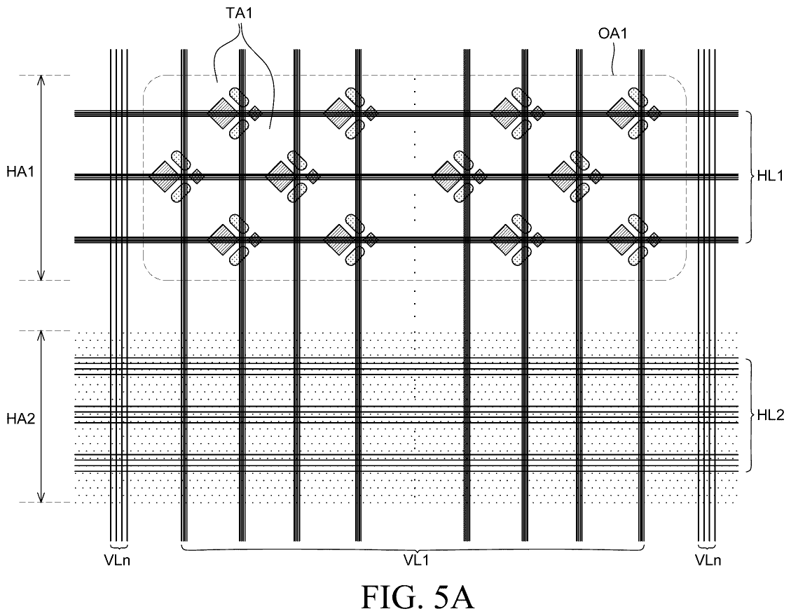

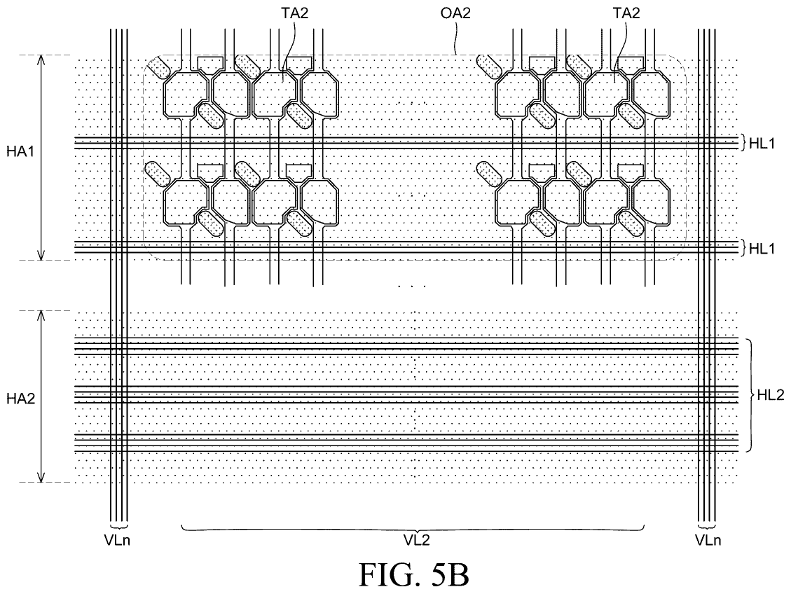

FIG. 5A is a view illustrating an example in which the signal lines are disposed in the first optical area and the normal area in the display panel according to the embodiment of the present specification. FIG. 5B is a view illustrating an example in which the signal lines are disposed in the second optical area and the normal area in the display panel according to the embodiment of the present specification.

FIG. 5A illustrates the arrangement of the signal lines in the first optical area OA1 and the normal area NA of the display panel DP according to the embodiment of the present specification. FIG. 5B illustrates the arrangement of the signal lines in the second optical area OA2 and the normal area NA of the display panel DP according to the embodiment of the present specification.

FIG. 5A illustrates a part of the first horizontal display area HA1 and a part of the first optical area OA1. FIG. 5B illustrates a part of the second horizontal display area HA2 and a part of the second optical area OA2. In addition, as illustrated in FIGS. 5A and 5B, the first horizontal display area HA1 includes the normal area NA, the first optical area OA1, and the second optical area OA2, and the second horizontal display area HA2 includes only the normal area NA.

Various types of horizontal lines HL1 and HL2 and various types of vertical lines VLn, VL1, and VL2 may be disposed on the display panel DP.

With reference to FIGS. 5A and 5B, horizontal lines disposed on the display panel DP may include a first horizontal line HL1 disposed in the first horizontal display area HA1, and a second horizontal line HL2 disposed in the second horizontal display area HA2. In this case, the first horizontal line HL1 and the second horizontal line HL2 may each be the gate line. The gate line may include various types of gate lines in accordance with the structure of the subpixel.

With reference to FIGS. 5A and 5B, the vertical line disposed on the display panel DP may include a normal vertical line VLn disposed only in the normal area, a first vertical line VL1 configured to pass through both the first optical area OA1 and the normal area, and a second vertical line VL2 configured to pass through both the second optical area OA2 and the normal area.

The vertical line disposed on the display panel DP may include a data line, a drive voltage line, and the like. Further, the vertical line may further include a reference voltage line, an initialization voltage line, and the like. That is, the normal vertical line VLn, the first vertical line VL1, and the second vertical line VL2 may each include the data line, the drive voltage line, and the like and further include the reference voltage line, the initialization voltage line, and the like.

With reference to FIGS. 4 and 5A, the first optical area OA1 included in the first horizontal area HA1 may include the light-emitting area EA and the first transmissive area TA1. In the first optical area OA1, an outer area of the first transmissive area TA1 may include the light-emitting area EA.

With reference to FIG. 5A, in order to improve the transmittance of the first optical area OA1, the first horizontal line HL1 passing through the first optical area OA1 may extend while bypassing the first transmissive area TA1 in the first optical area OA1. Therefore, the first horizontal line HL1 passing through the first optical area OA1 may include a curved section, a bending section, or the like that bypasses a portion disposed outside an outer peripheral rim of the first transmissive area TA1. The first horizontal line HL1, which passes through the first optical area OA1, and the second horizontal line HL2, which does not pass through the first optical area OA1, may be different in shape or length.

In addition, in order to improve the transmittance of the first optical area OA1, the first vertical line VL1 passing through the first optical area OA1 may extend while bypassing the first transmissive area TA1 in the first optical area OA1. Therefore, the first vertical line VL1 passing through the first optical area OA1 may include a curved section, a bending section, or the like that bypasses a portion disposed outside an outer peripheral rim of the first transmissive area TA1. The first vertical line VL1, which passes through the first optical area OA1, and the normal vertical line VLn, which is disposed in the normal area NA without passing through the first optical area OA1, may be different in shape or length.

With reference to FIG. 5A, the first transmissive areas TA1 included in the first optical area OA1 in the first horizontal area HA1 may be arranged in an oblique direction. With reference to FIG. 5A, the light-emitting area may be disposed between the two first transmissive areas TA1, which are disposed adjacent to each other in the leftward/rightward direction, in the first optical area OA1 in the first horizontal area HA1. The light-emitting area may be disposed between the two first transmissive areas, which are disposed adjacent to each other in the upward/downward direction, in the first optical area OA1 in the first horizontal area HA1.

With reference to FIGS. 4 and 5B, the second optical area OA2 included in the first horizontal area HA1 may include the light-emitting area EA and the second transmissive area TA2. In the second optical area OA2, an outer area of the second transmissive area TA2 may include the light-emitting area EA.

As illustrated in FIG. 5B, the positions and arrangement states of the light-emitting area EA and the second transmissive area TA2 in the second optical area OA2 may be different from the positions and arrangement states of the light-emitting area EA and the first transmissive area TA1 in the first optical area OA1 in FIG. 5A. However, the positions and arrangement states of the light-emitting area EA and the second transmissive area TA2 in the second optical area OA2 may be identical to the positions and arrangement states of the light-emitting area EA and the first transmissive area TA1 in the first optical area OA1 in FIG. 5A.

With reference to FIG. 5B, the second transmissive areas TA2 may be arranged in the horizontal direction (leftward/rightward direction) in the second optical area OA2, and the light-emitting area EA may not be disposed between the two second transmissive areas TA2 adjacent to each other in the horizontal direction (leftward/rightward direction). In addition, the second transmissive areas TA2 may be arranged in the vertical direction (upward/downward direction) in the second optical area OA2, and the light-emitting area EA may be disposed between the second transmissive areas TA2 adjacent to each other in the vertical direction (upward/downward direction). That is, the light-emitting area EA may be disposed between the two rows of the second transmissive areas TA2.

The positions and arrangement states of the light-emitting area and the second transmissive area TA2 in the second optical area OA2 in FIG. 5B are different from the positions and arrangement states of the light-emitting area and the second transmissive area in the first optical area OA1 in FIG. 5A. Therefore, as illustrated in FIG. 5B, the first horizontal line HL1 may pass through the second optical area OA2 in the first horizontal area HA1 and the normal area at the periphery of the second optical area OA2 in a shape different from the shape illustrated in FIG. 5A. However, the first horizontal line HL1 may pass through the second optical area OA2 in the first horizontal area HA1 and the normal area at the periphery of the second optical area OA2 in the same shape as illustrated in FIG. 5A.

With reference to FIG. 5B, when the first horizontal line HL1 passes through the second optical area OA2 in the first horizontal area HA1 and the normal area NA at the periphery of the second optical area OA2, the first horizontal line HL1 may pass in a straight shape, without having a curved section or a bending section, between the second transmissive areas TA2 disposed adjacent to each other in the upward/downward direction. For example, one first horizontal line HL1 has a curved section or a bending section in the first optical area OA1 but may not have a curved section or a bending section in the second optical area OA2.

In addition, in order to improve the transmittance of the second optical area OA2, the second vertical line VL2 passing through the second optical area OA2 may extend while bypassing the second transmissive area TA2 in the second optical area OA2. As illustrated in FIG. 5B, the second vertical line VL2 passing through the second optical area OA2 may include a curved section, a bending section, or the like that bypasses a portion disposed outside an outer peripheral rim of the second transmissive area TA2. Therefore, the second vertical line VL2, which passes through the second optical area OA2, and the normal vertical line VLn, which is disposed in the normal area without passing through the second optical area OA2, may be different in shape or length.

In case that the first horizontal line HL1 passing through the first optical area OA1 have curved sections or bending sections that bypass the portion disposed outside the outer peripheral rim of the first transmissive area TA1, a length of the first horizontal line HL1 passing through the first optical area OA1 and the second optical area OA2 may be longer than a length of the second horizontal line HL2 disposed only in the normal area NA.

Therefore, resistance (hereinafter, referred to as ‘first resistance’) of the first horizontal line HL1, which passes through the first optical area OA1 and the second optical area OA2, may be higher than resistance (hereinafter, referred to as ‘second resistance’) of the second horizontal line HL2 disposed only in the normal area NA.

The first optical area OA1, which at least partially overlaps the first electronic optical device 170a, includes the plurality of first transmissive areas TA1, and the second optical area OA2, which at least partially overlaps the second electronic optical device 170b, includes the plurality of second transmissive areas TA2. Therefore, the number of subpixels, to which the first horizontal line HL1 passing through the first optical area OA1 and the second optical area OA2 is connected, may be different from the number of subpixels to which the second horizontal line HL2, which is disposed only in the normal area NA without passing through the first optical area OA1 and the second optical area OA2, is connected.

That is, the first optical area OA1 and the second optical area OA2 may be smaller in number of subpixels per unit area than the normal area NA.

The number (first number) of subpixels, to which the first horizontal line HL1 passing through the first optical area OA1 and the second optical area OA2 is connected, may be smaller than the number (second number) subpixels to which the second horizontal line HL2 disposed only in the normal area NA is connected.

A difference between the first number and the second number may vary depending on a difference between the resolution of each of the first optical area OA1 and the second optical area OA2 and the resolution of the normal area NA. For example, the difference between the first number and the second number may increase as the difference between the resolution of each of the first optical area OA1 and the second optical area OA2 and the resolution of the normal area NA increases.

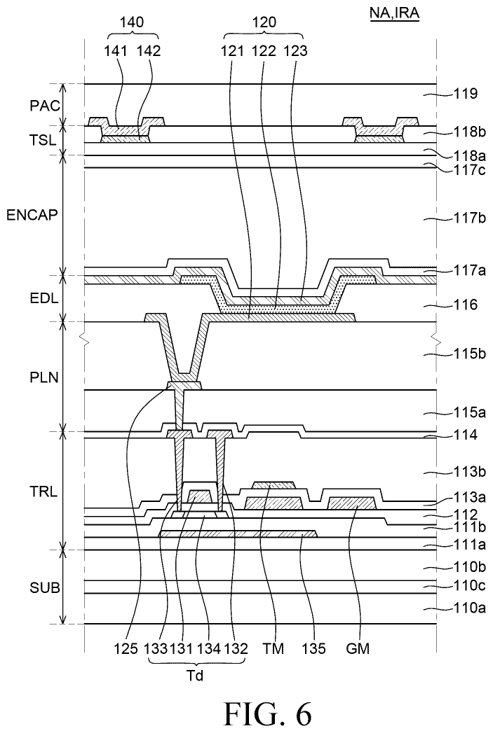

Hereinafter, cross-sectional structures of the normal area NA and the infrared ray-emitting area IRA of the display device 100 according to the embodiment of the present specification will be described in detail with reference to FIG. 6.

FIG. 6 is a view illustrating a cross-sectional structure of one subpixel disposed in the normal area and the infrared ray-emitting area in the display panel according to the embodiment of the present specification.

The subpixel is a minimum unit that constitutes a screen. A plurality of light-emitting elements 120 may be included and respectively correspond to the plurality of subpixels. That is, the plurality of light-emitting elements 120 may be disposed to respectively correspond to the plurality of subpixels. Therefore, the plurality of subpixels may be represented as the plurality of light-emitting elements 120.

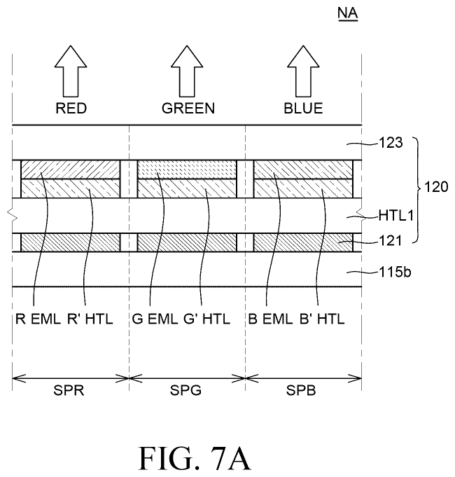

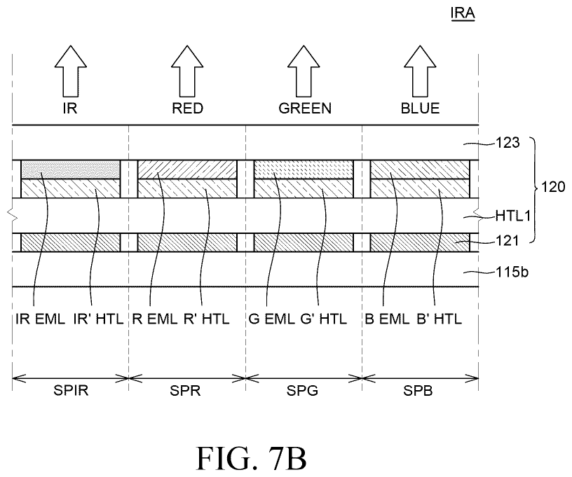

The plurality of subpixels may emit light beams having different wavelengths. For example, in the normal area NA, the plurality of subpixels may include a red subpixel SPR, a green subpixel SPG, and a blue subpixel SPB. Meanwhile, in the infrared ray-emitting area IRA, the plurality of subpixels may include the red subpixel SPR, the green subpixel SPG, the blue subpixel SPB, and an infrared ray subpixel SPIR. A difference in structures between the plurality of subpixels in the normal area NA and the infrared ray-emitting area IRA will be described below with reference to FIGS. 7A and 7B.

In addition, FIG. 6 illustrates, as an example, any one subpixel among the plurality of subpixels disposed in the normal area NA and the infrared ray-emitting area IRA. However, the subpixels, which emit light beams with different colors, may be identical in overall structures, but the light beams outputted by light-emitting stacks, which constitute the light-emitting elements 120, are different from one another.

With reference to FIG. 6, in the normal area NA and the infrared ray-emitting area IRA, a transistor layer TRL may be disposed above a substrate SUB, and a planarization layer PLN may be disposed above the transistor layer TRL. A light-emitting element layer EDL may be disposed above the planarization layer PLN, the encapsulation layer ENCAP may be disposed above the light-emitting element layer EDL, a touch sensing layer TSL may be disposed above the encapsulation layer ENCAP, and a protective layer PAC may be disposed above the touch sensing layer TSL. In addition, an organic material layer PCL may be disposed above the protective layer PAC, and a polarizing layer POL may be disposed above the organic material layer PCL.

The substrate SUB is a component for supporting various constituent elements included in the display device 100 and may be made of an insulating material. The substrate SUB may include a first substrate 110a, a second substrate 110b, and an interlayer insulation film 110c. For example, the first substrate 110a and the second substrate 110b may each be a substrate made of polyimide (PI). The interlayer insulation film 110c may be disposed between the first substrate 110a and the second substrate 110b. As described above, the substrate SUB is configured by the first substrate 110a, the second substrate 110b, and the interlayer insulation film 110c, which may suppress moisture penetration.

In the normal area NA and the infrared ray-emitting area IRA, various types of patterns 131, 132, 133, and 134 for forming transistors such as a driving transistor Td, various types of insulation films 111a, 111b, 112, 113a, 113b, and 114, and various types of metal patterns TM, GM, and 135 may be disposed on the transistor layer TRL.

Hereinafter, a layered structure of the transistor layer TRL will be described in more detail.

A multi-buffer layer 111a may be disposed on the second substrate 110b, and a metal layer 135 may be disposed on the multi-buffer layer 111a. In this case, the metal layer 135 may serve as a light shield and be also referred to as a light-blocking layer.

An active buffer layer 111b may be disposed on the multi-buffer layer 111a and the metal layer 135, and an active layer 134 of the driving transistor Td may be disposed on the active buffer layer 111b. For example, the active layer 134 may be made of polysilicon (p-Si), amorphous silicon (a-Si), or oxide semiconductor. However, the present specification is not limited thereto.

A gate insulation film 112 may be disposed on the active layer 134. The gate insulation film 112 may be made of silicon oxide (SiOx), silicon nitride (SiNx), or a multilayer thereof.

In addition, a gate electrode 131 of the driving transistor Td may be disposed on the gate insulation film 112. The gate electrode 131 may be disposed on the gate insulation film 112 and overlap the active layer 134. The gate electrode 131 may be made of various electrically conductive materials, for example, magnesium (Mg), aluminum (Al), nickel (Ni), chromium (Cr), molybdenum (Mo), tungsten (W), gold (Au), or an alloy thereof. However, the present specification is not limited thereto.

A gate material layer GM may be disposed on the gate insulation film 112 and provided at a position different from a position at which the driving transistor Td is formed.

A first interlayer insulation film 113a may be disposed on the gate electrode 131 and the gate material layer GM. A metal pattern TM may be disposed on the first interlayer insulation film 113a. A second interlayer insulation film 113b may be disposed while covering the metal pattern TM disposed on the first interlayer insulation film 113a.

A source electrode 132 and a drain electrode 133 of the driving transistor Td may be disposed on the second interlayer insulation film 113b.

The source electrode 132 and the drain electrode 133 may be respectively connected to one side and the other side of the active layer 134 through contact holes provided in the second interlayer insulation film 113b, the first interlayer insulation film 113a, and the gate insulation film 112. The source electrode 132 and the drain electrode 133 may each be made of various electrically conductive materials, for example, magnesium (Mg), aluminum (Al), nickel (Ni), chromium (Cr), molybdenum (Mo), tungsten (W), gold (Au), or an alloy thereof. However, the present specification is not limited thereto.

A portion of the active layer 134, which overlaps the gate electrode 131, is the channel area. One of the source electrode 132 and the drain electrode 133 is connected to one side of the channel area of the active layer 134, and the other of the source electrode 132 and the drain electrode 133 is connected to the other side of the channel area of the active layer 134.

A passivation layer 114 may be disposed on the source electrode 132 and the drain electrode 133. The passivation layer 114 may serve to protect the driving transistor Td and be made of an inorganic film, for example, silicon oxide (SiOx), silicon nitride (SiNx), or a multilayer thereof.

The planarization layer PLN may be positioned above the transistor layer TRL. The planarization layer PLN may include a first planarization layer 115a and a second planarization layer 115b. The planarization layer PLN protects the driving transistor Td and planarizes an upper portion of the driving transistor Td. The first planarization layer 115a may be disposed on the passivation layer 114, and a connection electrode 125 may be disposed on the first planarization layer 115a.

The connection electrode 125 may be connected to one of the source electrode 132 and the drain electrode 133 through a contact hole provided in the first planarization layer 115a.

The second planarization layer 115b may be disposed on the connection electrode 125.

The light-emitting element layer EDL may be positioned above the second planarization layer 115b.

Hereinafter, a layered structure of the light-emitting element layer EDL will be described in detail.

The light-emitting element 120 including an anode 121, a light-emitting part 122, and a cathode 123 may be formed on the second planarization layer 115b.

The anode 121 may be disposed on the second planarization layer 115b. In this case, the anode 121 may be electrically connected to the connection electrode 125 through a contact hole provided in the second planarization layer 115b. The anode 121 may be made of a metallic material.

In case that the display device 100 is a top-emission type display device in which light emitted from the light-emitting element 120 propagates toward an upper side of the substrate SUB on which the light-emitting element 120 is disposed, the anode 121 may further include a transparent conductive layer, and a reflective layer disposed on the transparent conductive layer. For example, the transparent conductive layer may be made of transparent conductive oxide such as ITO or IZO. For example, the reflective layer may be made of silver (Ag), aluminum (Al), gold (Au), molybdenum (Mo), tungsten (W), chromium (Cr), or an alloy thereof.

A bank 116 may be disposed while covering the anode 121. In this case, a portion of the bank 116, which corresponds to the light-emitting area of the subpixel, may be opened. A part of the anode 121 may be exposed to the open area of the bank 116. The bank 116 may be made of an inorganic insulating material such as silicon nitride (SiNx) or silicon oxide (SiOx), or an organic insulating material such as benzocyclobutene-based resin, acrylic resin, or imide-based resin. However, the present specification is not limited thereto.

The light-emitting part 122 may be disposed in the open area of the bank 116 and an area at the periphery of the open area. That is, the light-emitting part 122 may be disposed on the anode 121 exposed through the open area of the bank 116. The light-emitting part 122 may include a plurality of organic films. The light-emitting part 122 serves to emit light. The light-emitting part 122 may include at least one of a hole injection layer (HIL), a hole transport layer (HTL), a light-emitting layer, an electron transport layer (ETL), and an electron injection layer (EIL). Some constituent elements of the light-emitting part 122 may be excluded depending on the structures or properties of the display device 100. In this case, an organic light-emitting layer and an inorganic light-emitting layer may be applied as the light-emitting layer.

The cathode 123 may be disposed on the light-emitting part 122.

The light-emitting elements 120 included in the subpixels may have different structures depending on the light beams emitted from the subpixels. A difference in structures of the light-emitting elements between the plurality of subpixels in the normal area NA and the infrared ray-emitting area IRA will be described below with reference to FIGS. 7A and 7B.

The encapsulation layer ENCAP may be positioned above the light-emitting element layer EDL.

The encapsulation layer ENCAP may have a single-layer or multilayer structure. For example, the encapsulation layer ENCAP may include a first encapsulation layer 117a, a second encapsulation layer 117b, and a third encapsulation layer 117c.

In this case, the first encapsulation layer 117a and the third encapsulation layer 117c may each be made of an inorganic film, and the second encapsulation layer 117b may be made of an organic film. Among the first encapsulation layer 117a, the second encapsulation layer 117b, and the third encapsulation layer 117c, the second encapsulation layer 117b may be thickest and serve as a planarization layer.

The first encapsulation layer 117a may be disposed on the cathode 123 and closest to the light-emitting element 120. The first encapsulation layer 117a may be made of an inorganic insulating material that may be deposited at a low temperature. For example, the first encapsulation layer 117a may be made of silicon nitride (SiNx), silicon oxide (SiOx), silicon oxynitride (SiON), aluminum oxide (Al₂O₃), or the like. Because the first encapsulation layer 117a is deposited in a low-temperature ambience, it is possible to suppress damage to the light-emitting part 122 made of an organic material vulnerable to a high-temperature ambience during a deposition process.

The second encapsulation layer 117b may have a smaller area than the first encapsulation layer 117a. In this case, the second encapsulation layer 117b may be formed to expose two opposite ends of the first encapsulation layer 117a. The second encapsulation layer 117b may serve as a buffer for mitigating stress between the layers caused when the flexible display device is bent. The second encapsulation layer 117b may serve to improve the planarization performance.

For example, the second encapsulation layer 117b may be made of an organic insulating material such as acrylic resin, epoxy resin, polyimide, polyethylene, or silicon oxycarbon (SiOC). For example, the second encapsulation layer 117b may also be formed in an inkjet manner. However, the present specification is not limited thereto.

The third encapsulation layer 117c may be formed above the substrate SUB having the second encapsulation layer 117b to cover a top surface and a side surface of each of the second encapsulation layer 117b and the first encapsulation layer 117a. In this case, the third encapsulation layer 117c may minimize or block the penetration of outside moisture or oxygen into the first encapsulation layer 117a and the second encapsulation layer 117b. For example, the third encapsulation layer 117c may be made of an inorganic insulating material such as silicon nitride (SiNx), silicon oxide (SiOx), silicon oxynitride (SiON), or aluminum oxide (Al₂O₃).

Although not illustrated in FIG. 6, a color filter may be disposed on the encapsulation layer ENCAP. However, the present specification is not limited thereto.

In addition, although not illustrated, a structure for blocking a flow of the second encapsulation layer 117b, which constitutes the encapsulation layer ENCAP, may be disposed in the non-display area NDA. In order to inhibit the encapsulation layer ENCAP from being collapsed, one or more structures may be disposed at an end point of an inclined surface of the encapsulation layer ENCAP or disposed at a position adjacent to the inclined surface of the encapsulation layer ENCAP. The one or more structures may be disposed at a boundary point between the display area DA and the non-display area NDA or disposed at a position adjacent to the boundary point. The structure may include one or more layers at least made of an organic material. For example, the structure may include a lower layer disposed on the same layer and made of the same material as the second planarization layer 115b, and an upper layer disposed on the same layer and made of the same material as the bank 116. However, the present specification is not limited thereto.

The touch sensing layer TSL may be disposed above the encapsulation layer ENCAP.

A touch buffer film 118a may be disposed above the encapsulation layer ENCAP, a touch line 140 may be disposed on the touch buffer film 118a.

The touch line 140 may include a touch sensor metal 141 and a bridge metal 142 positioned on different layers. A touch interlayer insulation film 118b may be disposed between the touch sensor metal 141 and the bridge metal 142.

For example, the touch sensor metal 141 may include a first touch sensor metal, a second touch sensor metal, and a third touch sensor metal that are disposed adjacent to one another. The first touch sensor metal and the second touch sensor metal may be electrically connected to each other. However, in case that the third touch sensor metal is present between the first touch sensor metal and the second touch sensor metal, the first touch sensor metal and the second touch sensor metal may be electrically connected to each other through the bridge metal 142 present on a layer different from the layer on which the first touch sensor metal and the second touch sensor metal are disposed. The bridge metal 142 may be insulated from a third touch sensor metal by the touch interlayer insulation film 118b.

During a process of forming the touch sensing layer TSL, a liquid chemical (a developer, an etching liquid, or the like) used for the process may be produced, or moisture or the like may be produced from the outside. Therefore, the touch buffer film 118a may be disposed, and the touch sensing layer TSL may be disposed on the touch buffer film 118a, which may inhibit moisture or a liquid chemical, which is produced during the process of manufacturing the touch sensing layer TSL, from penetrating into the light-emitting part 122 including an organic material.

As describe above, the touch buffer film 118a may suppress damage to the light-emitting part 122 vulnerable to a liquid chemical or moisture. In order to suppress damage to the light-emitting part 122 including an organic material vulnerable to a high temperature, the touch buffer film 118a may be made of an organic insulating material that may be formed at a predetermined low temperature (e.g., 100° C. or less) and have low permittivity of 1 to 3. For example, the touch buffer film 118a may be made of an acrylic-based, epoxy-based, or siloxane-based material.

The display device 100 according to the embodiment of the present specification may be a flexible display device. When the flexible display device is bent, the encapsulation layer ENCAP may be damaged. In this case, the touch sensor metal 141 positioned above the touch buffer film 118a may be broken. Therefore, the touch buffer film 118a according to the embodiment of the present specification is made of an organic insulating material and has the planarization performance. Therefore, it is possible to suppress damage to the encapsulation layer ENCAP and inhibit the metals 141 and 142, which constitute the touch line 140, from being broken even though the flexible display device is bent.

The protective layer PAC (119) may be disposed to cover the touch line 140. The protective layer 119 may be made of an organic insulation film.

Although not illustrated in FIG. 6, the polarizing layer may be disposed on an organic material layer 150. The polarizing layer suppresses the reflection of external light in the display area DA of the substrate SUB. In addition, although not illustrated in FIG. 6, a cover glass may be bonded onto the polarizing layer by a bonding layer.

The light-emitting elements 120 of the subpixels disposed in the normal area NA and the infrared ray-emitting area IRA of the display device 100 according to the embodiment of the present specification will be described more specifically with reference to FIGS. 7A and 7B.

FIG. 7A is a schematic cross-sectional view for explaining the light-emitting elements of the plurality of subpixels disposed in one unit pixel disposed in the normal area of the display device according to the embodiment of the present specification. FIG. 7B is a schematic cross-sectional view for explaining the light-emitting elements of the plurality of subpixels disposed in one unit pixel disposed in the infrared ray-emitting area of the display device according to the embodiment of the present specification.

First, with reference to FIG. 7A, as described with reference to FIG. 4, one unit pixel disposed in the normal area NA may include the red subpixel SPR, the green subpixel SPG, and the blue subpixel SPB.

With reference to FIGS. 6 and 7A, the subpixels SPR, SPG, and SPB each including the light-emitting element 120 including the anode 121 disposed on the second planarization layer 115b, the light-emitting part 122 disposed on the anode 121 exposed through the open area of the bank 116, and the cathode 123 disposed on the light-emitting part 122.

The light-emitting part 122 may include at least one of a hole injection layer (HIL), a hole transport layer (HTL), a light-emitting layer (emitting material layer (EML)), an electron transport layer (ETL), and an electron injection layer (EIL).

The hole injection layer (HIL) (not illustrated) is disposed on the anode 121 and serves to facilitate the injection of the positive holes. For example, the hole injection layer may be made of any one or more of HAT-CN (dipyrazino[2,3-f:2′,3′-h]quinoxaline-2,3,6,7,10,11-hexacarbonitrile), CuPc (phthalocyanine), and NPD (N,N′-bis(naphthalene-1-yl)-N,N′-bis(phenyl)-2, 2′-dimethylbenzidine).

A first hole transport layer HTL1 is disposed on the hole injection layer and serves to smoothly transmit the positive holes to the light-emitting layer. For example, the first hole transport layer HTL1 may be made of any one or more of NPD (N,N′-bis(naphthalene-1-yl)-N,N′-bis (phenyl)-2,2′-dimethylbenzidine), TPD (N,N′-bis-(3-methylphenyl)-N,N′-bis-(phenyl)-benzidine), s-TAD (2,2′,7,7′-tetrakis (N,N-dimethylamino)-9,9-spirofluorene), and MTDATA (4, 4′, 4″-Tris (N-3-methylphenyl-N-phenyl-amino)-triphenylamine).

Auxiliary hole transport layers R′HTL, G′HTL, and B′HTL may be formed on a first hole transport layer HTL and formed independently in the red subpixel SPR, the green subpixel SPG, and the blue subpixel SPB. The auxiliary hole transport layers R′HTL, G′HTL, and B′HTL independently serve to smoothly transmit positive holes from the hole injection layer to the light-emitting layers.

The auxiliary hole transport layers R′HTL, G′HTL, and B′HTL may have different thicknesses for the red subpixel SPR, the green subpixel SPG, and the blue subpixel SPB. The thicknesses of the auxiliary hole transport layers R′HTL, G′HTL, and B′HTL may define optical distances of micro-cavities. For example, the auxiliary hole transport layers R′HTL, G′HTL, and B′HTL formed for the red subpixel SPR, the green subpixel SPG, and the blue subpixel SPB may be determined so that the light-emitting layer forms a micro-cavity structure between the anode 121 and the cathode 123.

Meanwhile, the auxiliary hole transport layer may be excluded in some subpixels. For example, in consideration of the micro-cavity, the auxiliary hole transport layers may be formed only in the red subpixel SPR and the green subpixel SPG without being formed in the blue subpixel SPB.

The light-emitting layers are formed on the auxiliary hole transport layers R′HTL, G′HTL, and B′HTL for the red subpixel SPR, the green subpixel SPG, and the blue subpixel SPB. The light-emitting layer may include a material capable of emitting light in a visible ray range by receiving and combining positive holes and electrons.

The light-emitting layers may be divided into a red light-emitting layer R EML, a green light-emitting layer G EML, and a blue light-emitting layer B EML in areas corresponding to the red subpixel SPR, the green subpixel SPG, and the blue subpixel SPB, and the light-emitting layers may have different thicknesses. A material known in the technical field may be used as the material of the light-emitting layer. For example, a material with good quantum efficiently for fluorescence or phosphorescence may be used as the material of the light-emitting layer.

The electron transport layer is disposed on the light-emitting layer to smoothly move electrons to the light-emitting layer. For example, the electron transport layer may be made of any one or more of Liq (8-hydroxyquinolinolato-lithium), PBD (2-(4-biphenyl)-5-(4-tert-butylphenyl)-1,3,4-oxadiazole), TAZ (3-(4-biphenyl) 4-phenyl-5-tert-butylphenyl-1,2,4-triazole), spiro-PBD, BCP (2,9-Dimethyl-4,7-diphenyl-1,10-phenanthroline), and Balq (bis(2-methyl-8-quinolinolate)-4-(phenylphenolato) aluminum).

An electron injection layer may be further disposed on the electron transport layer. The electron injection layer is an organic layer that facilitates the injection of electrons from a cathode 336. The electron injection layer may be eliminated depending on the structure and properties of the display device 100. The electron injection layer may be made of a metal inorganic compound such as BaF2, LiF, NaCl, CsF, Li₂O, and BaO or any one or more organic compounds among HAT-CN (dipyrazino[2,3-f:2′,3′-h]quinoxaline-2,3,6,7,10,11-hexacarbonitrile), CuPc (phthalocyanine), and NPD (N,N′-bis(naphthalene-1-yl)-N,N′-bis(phenyl)-2,2′-dimethylbenzidine).

An electron blocking layer for blocking a flow of electrons or a hole blocking layer for blocking a flow of positive holes is further disposed at a position adjacent to the light-emitting layer. Therefore, it is possible to inhibit the electron from moving from the light-emitting layer and passing through the adjacent hole transport layer when the electrons are injected into the light-emitting layer or inhibit the positive hole from moving from the light-emitting layer and passing through the adjacent electron transport layer when the positive holes are injected into the light-emitting layer, thereby improving luminous efficiency.

Next, with reference to FIG. 7B, as described with reference to FIG. 4, one unit pixel disposed in the infrared ray-emitting area IRA may include the red subpixel SPR, the green subpixel SPG, the blue subpixel SPB, and the infrared ray subpixel SPIR.

With reference to FIGS. 6 and 7B, the subpixels SPR, SPG, SPB, and SPIR disposed in the infrared ray-emitting area IRA each including the light-emitting element 120 including the anode 121 disposed on the second planarization layer 115b, the light-emitting part 122 disposed on the anode 121 exposed through the open area of the bank 116, and the cathode 123 disposed on the light-emitting part 122.

The light-emitting element 120 of each of the red subpixel SPR, the green subpixel SPG, and the blue subpixel SPB disposed in the infrared ray-emitting area IRA illustrated in FIG. 7B is substantially identical in structure to the light-emitting element 120 of each of the subpixels SPR, SPG, and SPB disposed in the normal area NA described above with reference to FIG. 7A. Therefore, a repeated description thereof will be omitted.

With reference to FIG. 7B, the infrared ray subpixel SPIR disposed in the infrared ray-emitting area IRA includes the light-emitting element 120 including the anode 121, the light-emitting part 122, and the cathode 123 disposed on the second planarization layer 115b. In this case, the light-emitting part 122 of the infrared ray subpixel SPIR includes the first hole transport layer HTL1, an auxiliary hole transport layer IR′HTL, and an infrared ray-emitting layer IR EML. The remaining components, which exclude the infrared ray-emitting layer IR EML constituting the light-emitting part 122 of the infrared ray subpixel SPIR, are substantially identical to the corresponding components constituting the light-emitting elements 120 of the red subpixel SPR, the green subpixel SPG, and the blue subpixel SPB. Therefore, a repeated description thereof will be omitted.

The infrared ray-emitting layer IR EML may be made of a material that emits light in the near infrared ray-emitting area IRA with a wavelength of 700 nm to 1100 nm. For example, the infrared ray-emitting layer IR EML may be made of at least one of organic complexes with trivalent rare-earth ions, ethyne-bridged porphyrin oligomers embedded in a polymer, Ir (III) complexes with extended systems, and platinum-porphyrin.

For example, the infrared ray-emitting layer IR EML may include compounds listed in Tables 1 to 8.

The compounds listed in Table 1 below are materials with PL emission in 700 nm to 1100 nm.

TABLE 1

| | IR1-1 |
|---|---|
| | (λ_{ϵm,solid} 860 nm) |
| Molecular Structure | 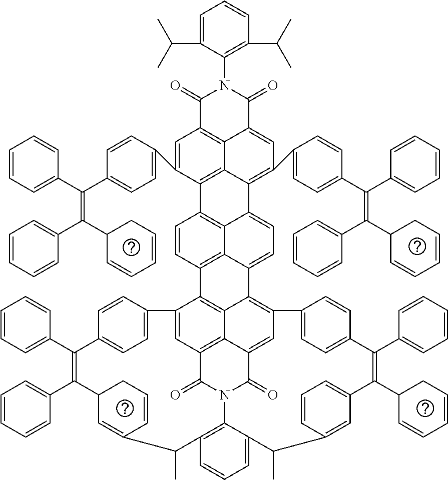 [SMILES: CC(C)c1cccc(C(C)C)c1N1C(=O)c2cc(-c3ccc(/C(=C(\c4ccccc4)C4C=CC=CC4)c4ccccc4)cc3)c3c4ccc5c6c7cc8c9c%10cc(c(c%11ccc(c%12c(-c%13ccc(/C(=C(/c%14ccccc%14)C%14C=CC=CC%14)c%14ccccc%14)cc%13)cc(c2c3%12)C1=O)c4c5%11)c96)-c1ccc(cc1)/C(c1ccccc1)=C(/c1ccccc1)C1C=C(C=CC1)C(C)c1cccc(c1N(C8=O)C%10=O)C(C)c1cccc(c1)/C(C1C=CC=CC1)=C(/c1ccccc1)c1ccc-7cc1] |
| | IR1-2 |
| | (λ_{ϵm,solid} 790 nm) |
| Molecular Structure | 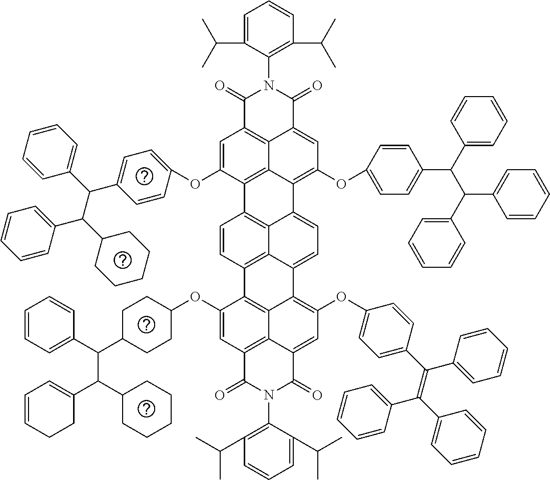 [SMILES: CC(C)c1cccc(C(C)C)c1N1C(=O)c2cc(Oc3ccc(C(c4ccccc4)C(c4ccccc4)c4ccccc4)cc3)c3c4ccc5c6c(Oc7ccc(C(=C(c8ccccc8)c8ccccc8)c8ccccc8)cc7)cc7c8c(cc(OC9CCC(C(c%10ccccc%10)C(C%10=CC=CCC%10)C%10CCCCC%10)CC9)c(c9ccc(c%10c(Oc%11ccc(C(c%12ccccc%12)C(c%12ccccc%12)C%12CCCCC%12)cc%11)cc(c2c3%10)C1=O)c4c59)c86)C(=O)N(c1c(C(C)C)cccc1C(C)C)C7=O] |
| | IR1-3 |
| | (λ_{ϵm,solid} 780 nm) |
| Molecular Structure | 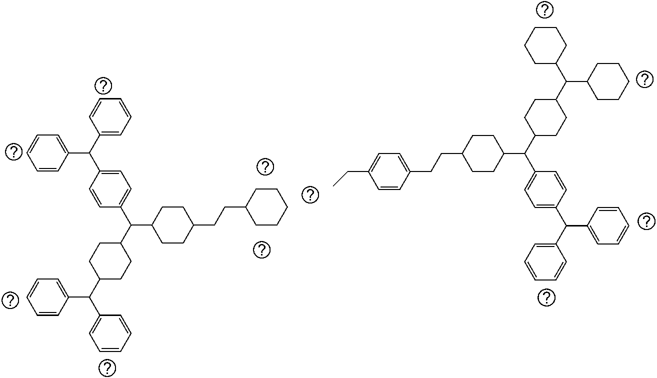 |
| | IR1-4 |
| | (λ_{ϵm,solid} 706 nm) |
| Molecular Structure | 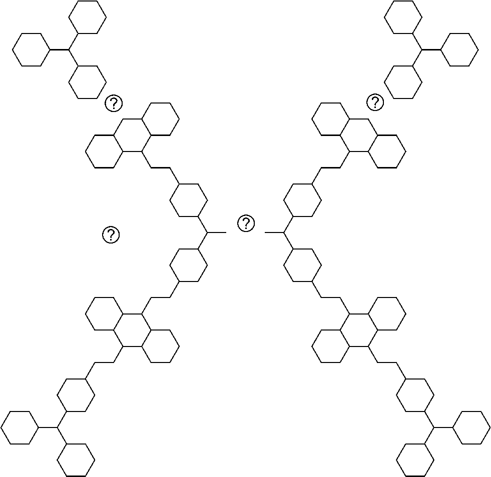 |
| | IR1-5 |
| | (λ_{ϵm,solid} 708 nm) |
| Molecular Structure | 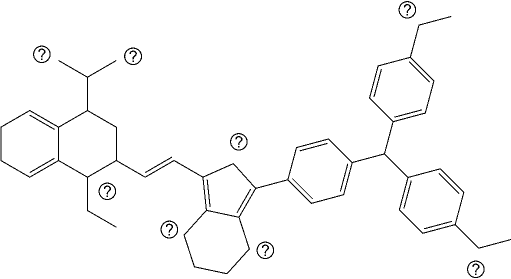 [SMILES: CCc1ccc(C(c2ccc(CC)cc2)c2ccc(C3=C4CCCCC4=C(/C=C/C4CC(C(C)C)C5=CCCC=C5C4CC)C3)cc2)cc1] |
| | IR1-6 |
| | (λ_{ϵm,solid} 738 nm) |
| Molecular Structure | 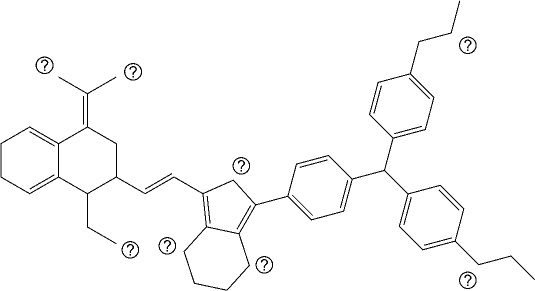 [SMILES: CCCc1ccc(C(c2ccc(CCC)cc2)c2ccc(C3=C4CCCCC4=C(/C=C/C4CC(=C(C)C)C5=CCCC=C5C4CC)C3)cc2)cc1] |
| | IR1-7 |
| | (λ_{ϵm,solid} 713 nm) |
| Molecular Structure | 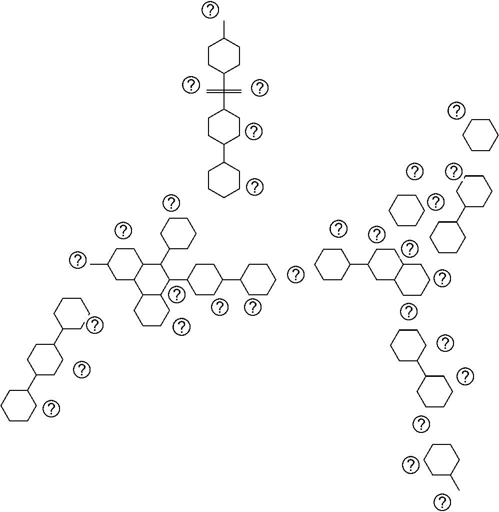 |
| | IR1-8 |
| | (λ_{ϵm,solid} 724 nm) |
| Molecular Structure | 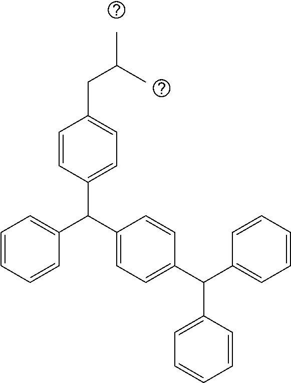 [SMILES: CC(C)Cc1ccc(C(c2ccccc2)c2ccc(C(c3ccccc3)c3ccccc3)cc2)cc1] |
| | IR1-9 |
| | (λ_{ϵm,solid} 1050 nm) |
| Molecular Structure | 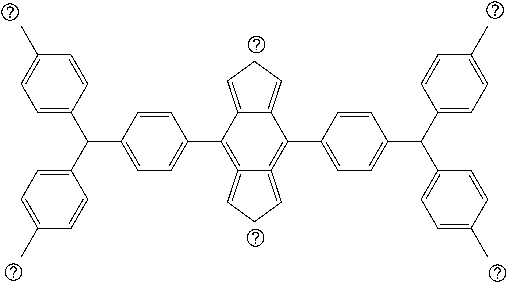 |
| | IR1-10 |
| | (λ_{ϵm,solid} 704 nm) |
| Molecular Structure | 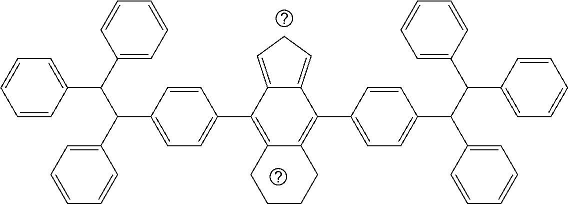 [SMILES: C1=c2c(-c3ccc(C(c4ccccc4)C(c4ccccc4)c4ccccc4)cc3)c3c(c(-c4ccc(C(c5ccccc5)C(c5ccccc5)c5ccccc5)cc4)c2=CC1)CCCC3] |
| | IR1-11 |
| | (λ_{ϵm,solid} 761 nm) |
| Molecular Structure | 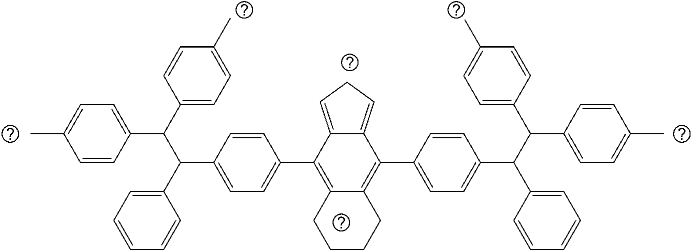 |
| | IR1-12 |
| | (λ_{ϵm,solid} 803 nm) |
| Molecular Structure | 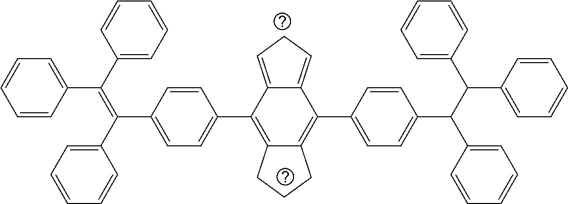 [SMILES: C1=c2c(-c3ccc(C(=C(c4ccccc4)c4ccccc4)c4ccccc4)cc3)c3c(c(-c4ccc(C(c5ccccc5)C(c5ccccc5)c5ccccc5)cc4)c2=CC1)CCC3] |
| | IR1-13 |
| | (λ_{ϵm,solid} 883 nm) |
| Molecular Structure | 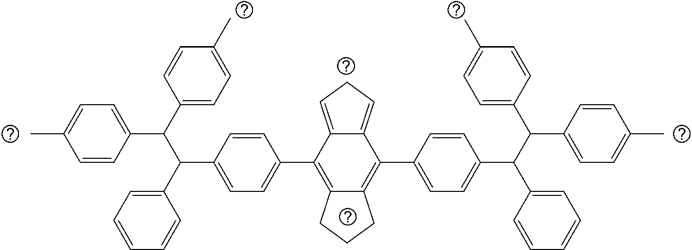 |
| | IR1-14 |
| | (λ_{ϵm,solid} 700 nm) |
| Molecular Structure | 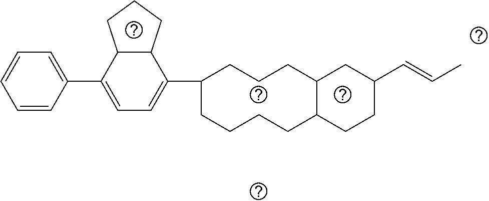 [SMILES: C/C=C/C1CCC2CCCCC(C3=CC=C(c4ccccc4)C4CCCC34)CCCC2C1] |
| | IR1-15 |
| | (λ_{ϵm,solid} 708 nm) |
| Molecular Structure | 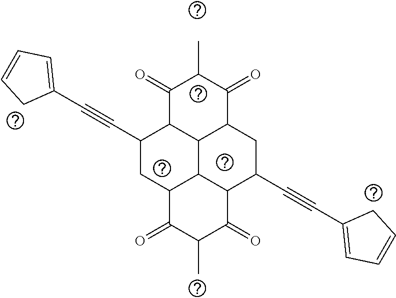 [SMILES: CC1C(=O)C2CC(C#CC3=CC=CC3)C3C(=O)C(C)C(=O)C4CC(C#CC5=CC=CC5)C(C1=O)C2C43] |

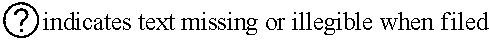

The compounds listed in Table 2 below are Pt-based materials with PL emission in 700 nm to 1100 nm.

TABLE 2

| | IR2-1 | IR2-2 |
|---|---|---|
| Molecular Structure | 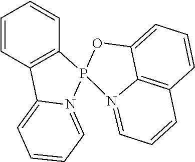 | 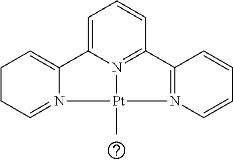 |
| | IR2-3 | IR2-4 |
| Molecular Structure | 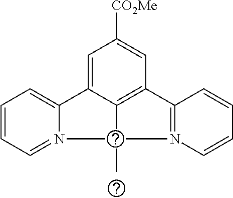 | 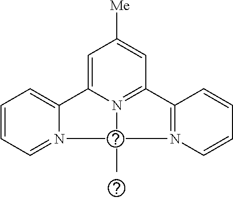 |
| | IR2-5 | IR2-6 |
| Molecular Structure | 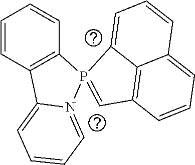 | 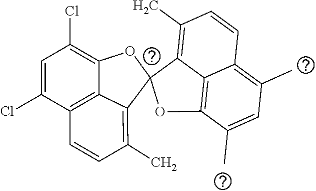 [SMILES: Cc1cc(C)c2ccc(C)c3c2c1OC31Oc2c(Cl)cc(Cl)c3ccc(C)c1c23] |
| | IR2-7 | IR2-8 |
| Molecular Structure | 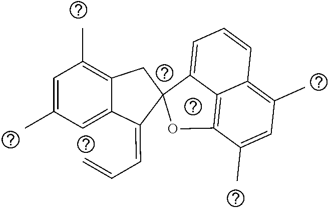 | 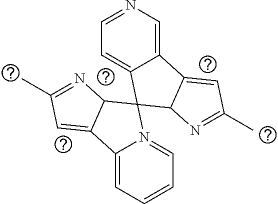 |
| | IR2-9 | IR2-10 |
| Molecular Structure | 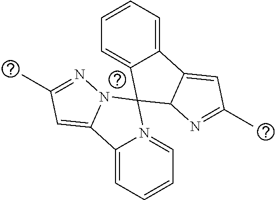 | 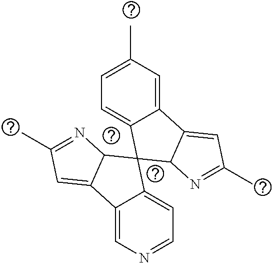 |
| | IR2-11 | IR2-12 |
| Molecular Structure | 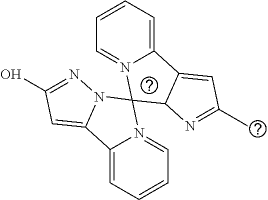 | 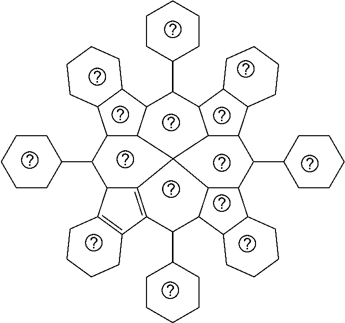 [SMILES: C1CCC(C2C3=C4C(C5=C3CCCC5)C(C3CCCCC3)C3C5CCCCC5C5C(C6CCCCC6)C6C7CCCCC7C7C(C8CCCCC8)C8C9CCCCC9C2C8C4(C35)C76)CC1] |
| | IR2-13 | IR2-14 |
| Molecular Structure | 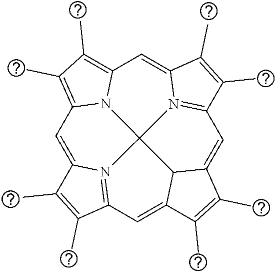 | 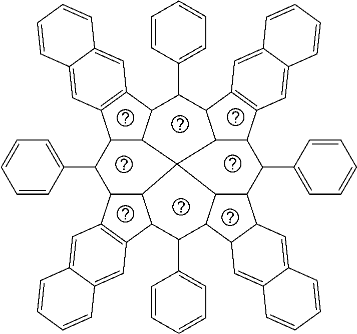 [SMILES: C1=c2ccccc2=CC2C1C1C(c3ccccc3)C3c4cc5ccccc5cc4C4C(c5ccccc5)C5c6cc7ccccc7cc6C6C(c7ccccc7)C7c8cc9ccccc9cc8C8C(c9ccccc9)C2C1C(C56)(C43)C78] |
| | IR2-15 | IR2-16 |
| Molecular Structure | 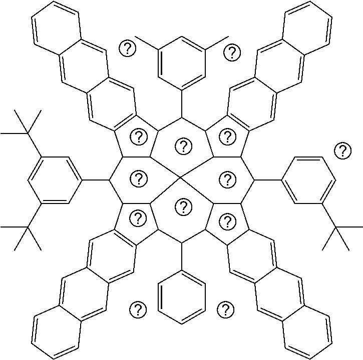 [SMILES: Cc1cc(C)cc(C2C3c4cc5cc6ccccc6cc5cc4C4C(c5cc(C(C)(C)C)cc(C(C)(C)C)c5)C5c6cc7cc8ccccc8cc7cc6C6C(c7ccccc7)C7C8C=c9cc%10ccccc%10cc9=CC8C8C(c9cccc(C(C)(C)C)c9)C9c%10cc%11cc%12ccccc%12cc%11cc%10C2C9C(C43)(C56)C78)c1] | 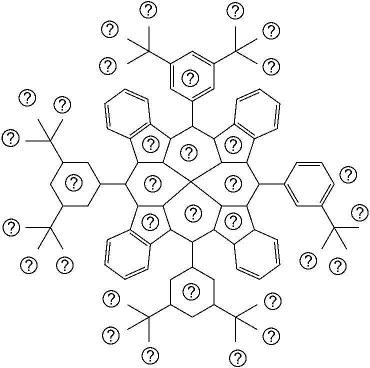 [SMILES: CC(C)(C)c1cccc(C2C3c4ccccc4C4C(c5cc(C(C)(C)C)cc(C(C)(C)C)c5)C5c6ccccc6C6C(C7CC(C(C)(C)C)CC(C(C)(C)C)C7)C7c8ccccc8C8C(C9CC(C(C)(C)C)CC(C(C)(C)C)C9)C9C%10C=CC=CC%10C2C9C(C43)(C56)C78)c1] |
| | IR2-17 | IR2-18 |
| Molecular Structure | 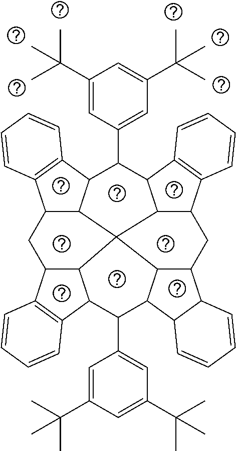 [SMILES: CC(C)(C)c1cc(C2C3c4ccccc4C4CC5c6ccccc6C6C(c7cc(C(C)(C)C)cc(C(C)(C)C)c7)C7C8C=CC=CC8C8CC9c%10ccccc%10C2C9C(C43)(C56)C87)cc(C(C)(C)C)c1] | 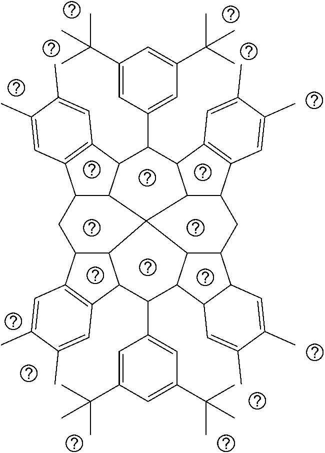 |
| | IR2-19 | IR2-20 |
| Molecular Structure | 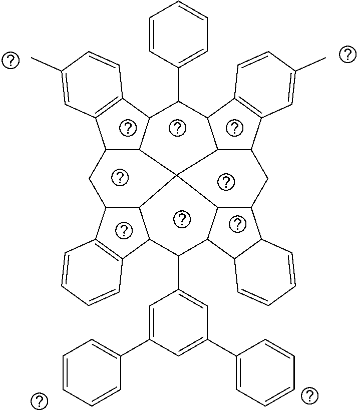 | 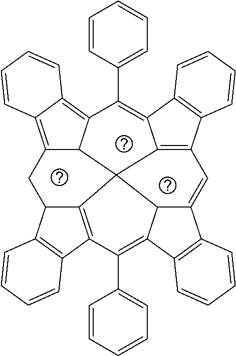 [SMILES: C1=C2c3ccccc3C3=C(c4ccccc4)C4=C5C(CC6=c7ccccc7=C7C(c8ccccc8)=C8C(=C1c1ccccc18)C5(C23)C67)c1ccccc14] |
| | IR2-21 | IR2-22 |
| Molecular Structure | 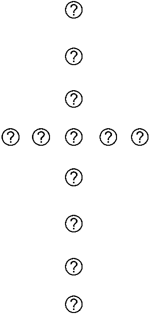 | 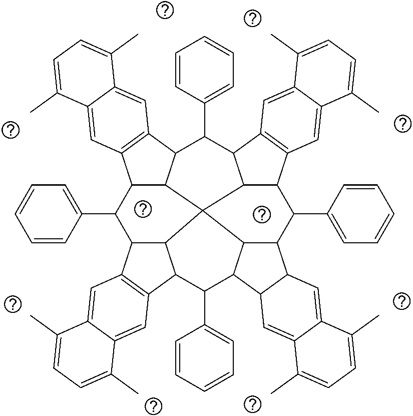 [SMILES: Cc1ccc(C)c2c1=CC1C(C=2)C2C(c3ccccc3)C3c4cc5c(C)ccc(C)c5cc4C4C(c5ccccc5)C5c6cc7c(C)ccc(C)c7cc6C6C(c7ccccc7)C7c8cc9c(C)ccc(C)c9cc8C8C(c9ccccc9)C1C2C(C65)(C78)C43] |
| | IR2-23 | IR2-24 |
| Molecular Structure | 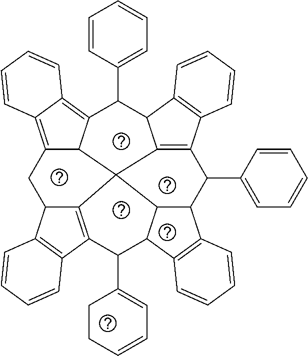 [SMILES: C1=CCCC(C2C3=C4C(CC5=c6ccccc6=C6C(c7ccccc7)C7C8=C(c9ccccc97)C(c7ccccc7)C7c9ccccc9C2C7C48C56)c2ccccc23)=C1] | 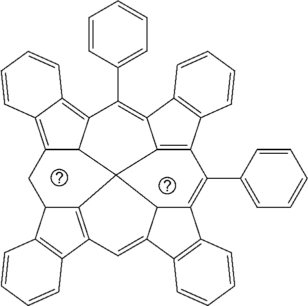 [SMILES: C1=C2c3ccccc3C3=C(c4ccccc4)C4=C5C(=C(c6ccccc6)C6=c7ccccc7=C7CC8C(=C1c1ccccc18)C5(C23)C76)c1ccccc14] |

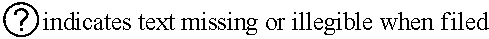

The compounds listed in Table 3 below are Ir-based materials with PL emission in 700 nm to 1100 nm.

TABLE 3

| | IR3-1 |
|---|---|
| Molecular Structure | 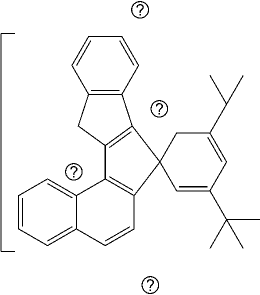 [SMILES: CC(C)C1=CC(C(C)(C)C)=CC2(C1)C1=C(Cc3ccccc31)c1c2ccc2ccccc12] |
| | IR2-2 |
| Molecular Structure | 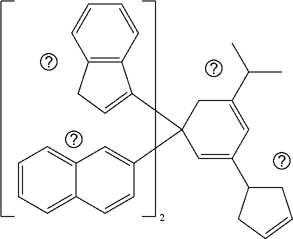 |
| | IR2-3 |
| Molecular Structure | 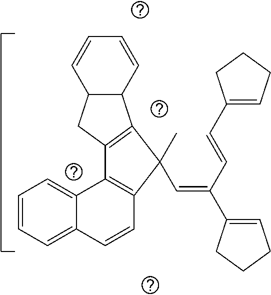 [SMILES: CC1(/C=C(\C=C\C2=CCCC2)C2=CCCC2)C2=C(CC3C=CC=CC23)c2c1ccc1ccccc21] |
| | IR2-4 |
| Molecular Structure | 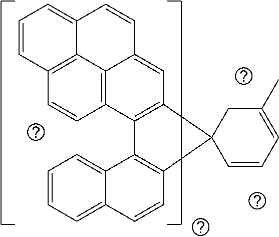 |
| | IR2-5 |
| Molecular Structure | 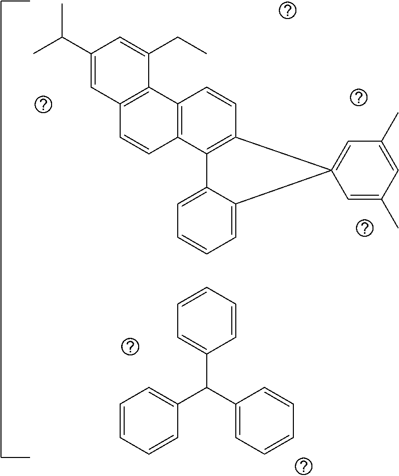 |
| | IR2-6 |
| Molecular Structure | 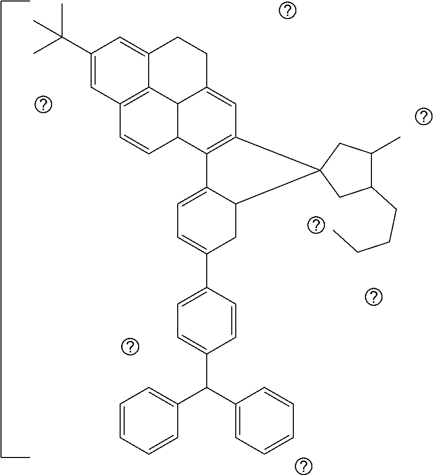 [SMILES: CCCCC1CC2(CC1C)C1=C(C3=CC=C(c4ccc(C(c5ccccc5)c5ccccc5)cc4)CC32)C2C=Cc3cc(C(C)(C)C)cc4c3C2C(=C1)CC4] |
| | IR2-7 |
| Molecular Structure | 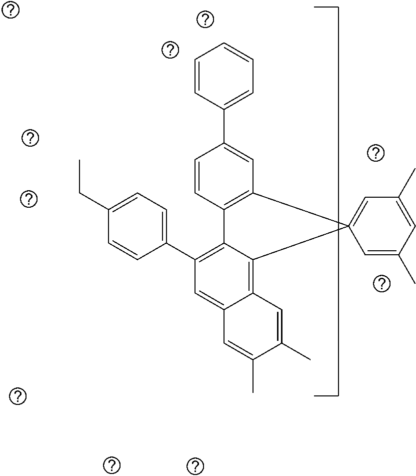 |
| | IR2-8 |
| Molecular Structure | 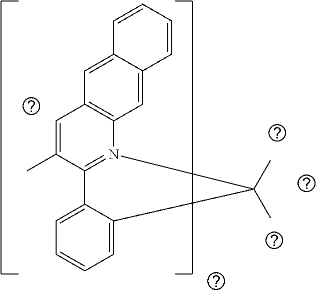 |
| | IR2-9 |
| Molecular Structure | 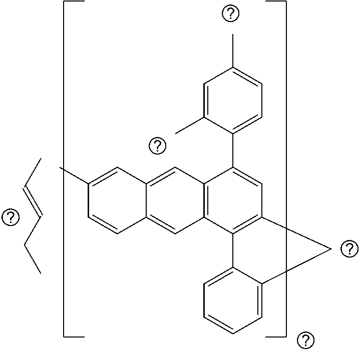 |
| | IR2-10 |
| Molecular Structure | 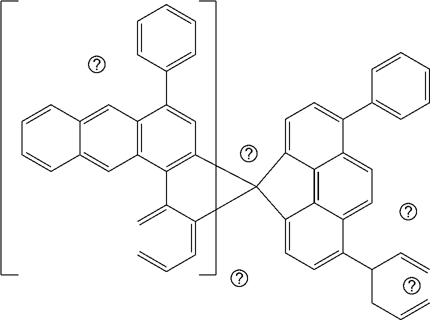 |
| | IR2-11 |
| Molecular Structure | 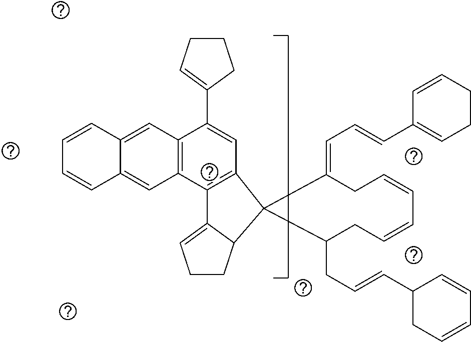 [SMILES: C1=CCC(/C=C/CC2C/C=C\C=C/C/C(=C\C=C\C3=CCCC=C3)C23c2cc(C4=CCCC4)c4cc5ccccc5cc4c2C2=CCCC23)C=C1] |
| | IR2-12 |
| Molecular Structure | 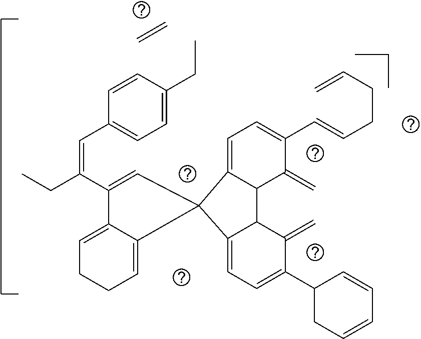 |
| | IR2-13 |
| Molecular Structure | 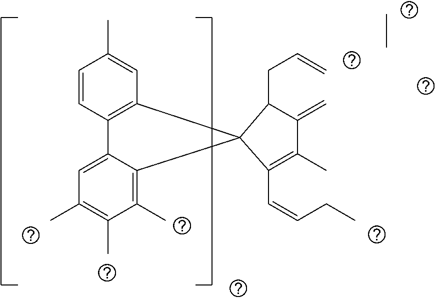 |
| | IR2-14 |
| Molecular Structure | 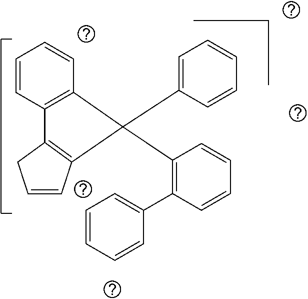 |
| | IR2-15 |
| Molecular Structure | 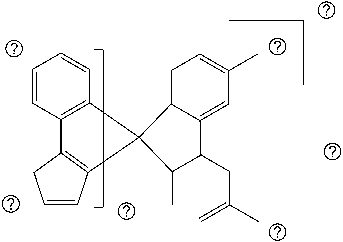 |
| | IR2-16 |
| Molecular Structure | 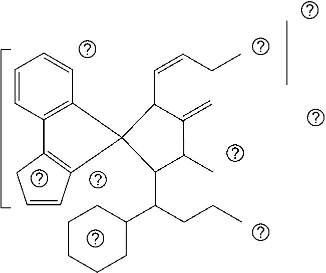 |
| | IR2-17 |
| Molecular Structure | 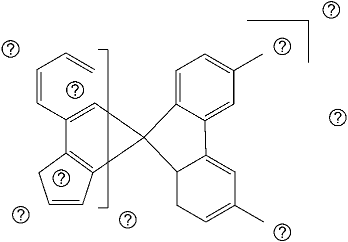 |
| | IR2-18 |
| Molecular Structure | 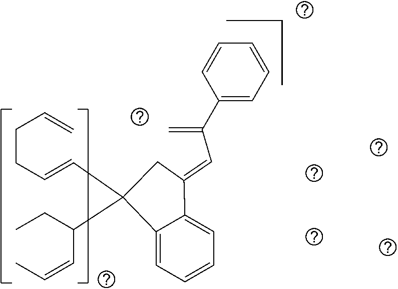 |
| | IR2-19 |
| Molecular Structure | 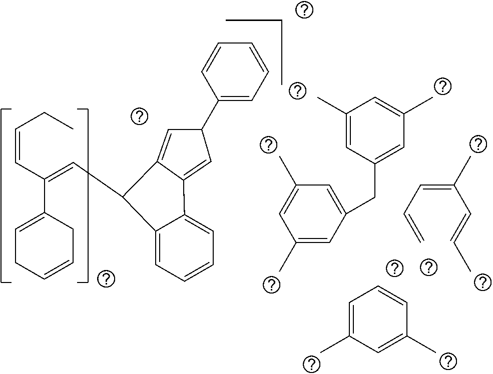 |
| | IR2-20 |
| Molecular Structure | 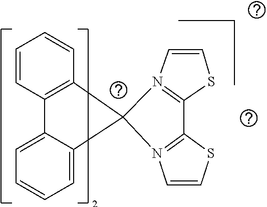 |
| | IR2-21 |
| Molecular Structure | 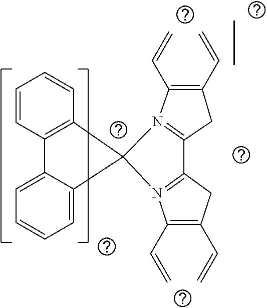 |
| | IR2-22 |
| Molecular Structure | 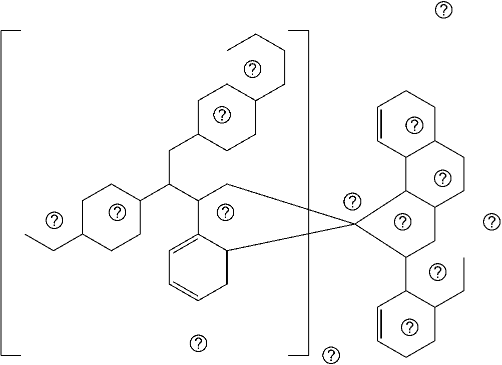 |
| | IR2-23 |
| Molecular Structure | 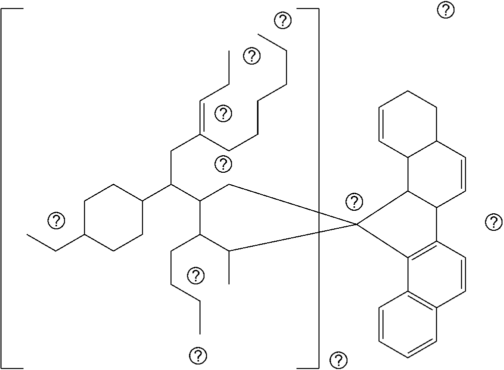 |
| | IR2-24 |
| Molecular Structure | 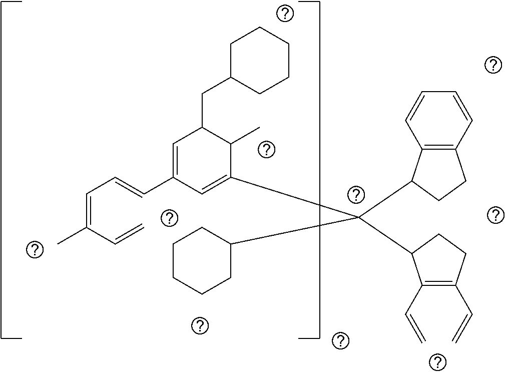 |
| | IR2-25 |
| Molecular Structure | 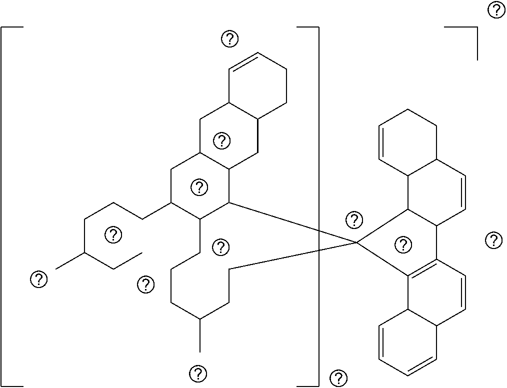 |
| | IR2-26 |
| Molecular Structure | 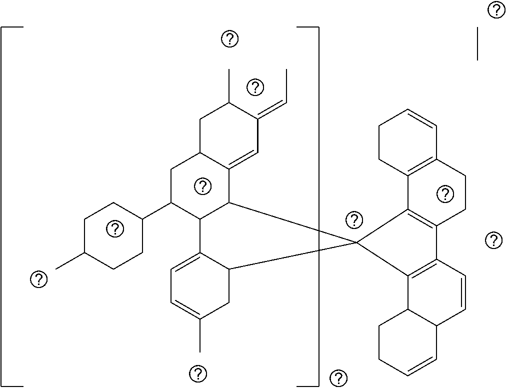 |
| | IR2-27 |
| Molecular Structure | 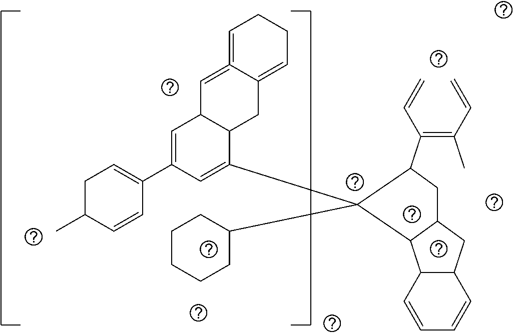 |

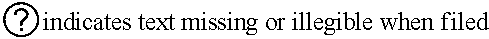

The compounds listed in Table 4 below are Ru-based materials with PL emission in 700 nm to 1100 nm.

TABLE 4

| | IR4-1 | IR4-2 |
|---|---|---|
| Molecular Structure | 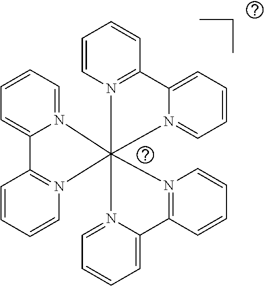 | 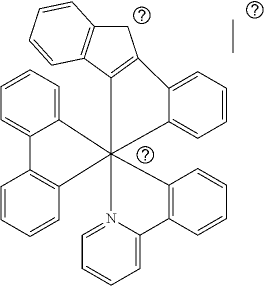 |
| | IR4-3 | IR4-4 |
| Molecular Structure | 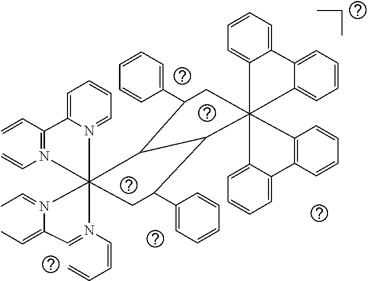 | 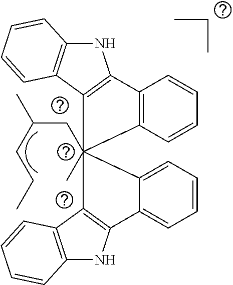 |
| | IR4-5 | IR4-6 |
| Molecular Structure | 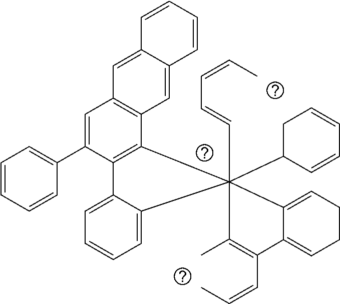 | 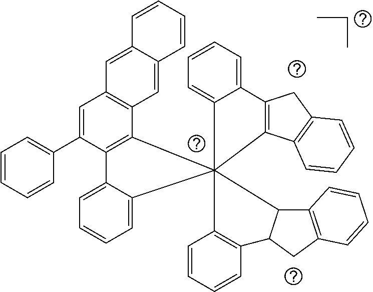 |
| | IR4-7 | IR4-8 |
| Molecular Structure | 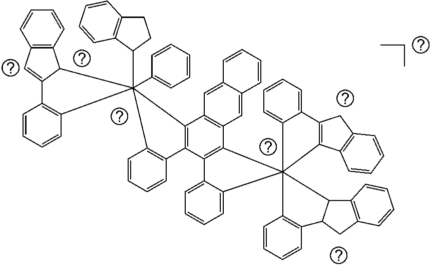 | 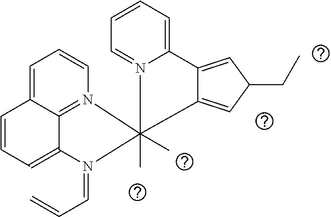 |
| | IR4-9 | IR4-10 |
| Molecular Structure | 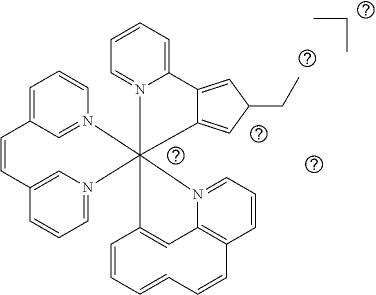 | 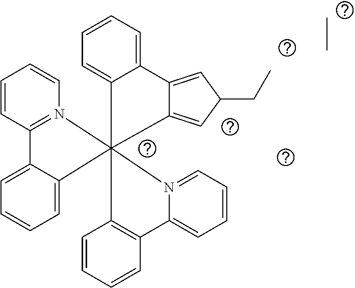 |
| | IR4-11 | IR4-12 |
| Molecular Structure | 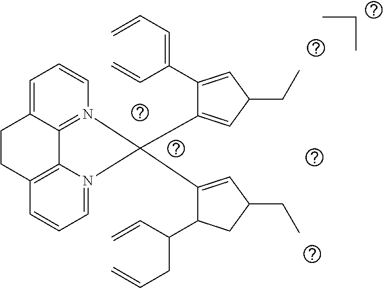 | 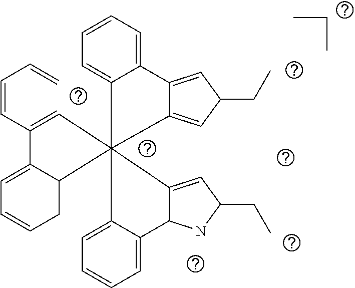 |
| | IR4-13 | IR4-14 |
| Molecular Structure | 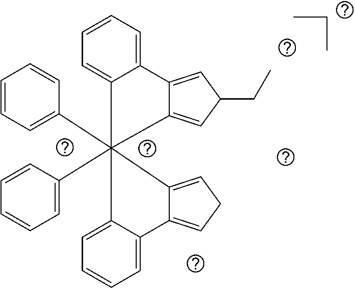 | 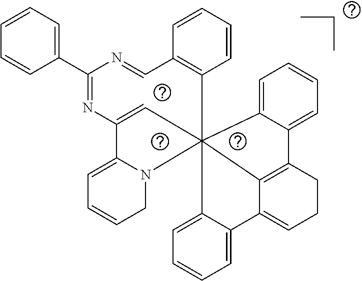 |
| | IR4-15 | IR4-16 |
| Molecular Structure | 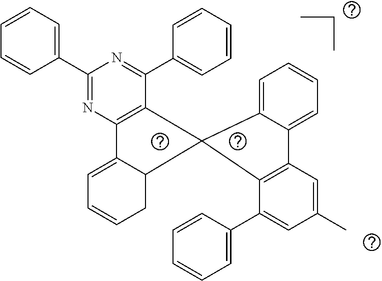 | 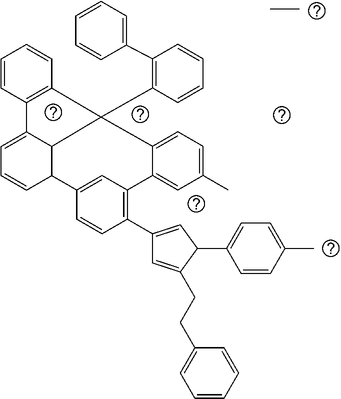 |
| | IR4-17 | IR4-18 |
| Molecular Structure | 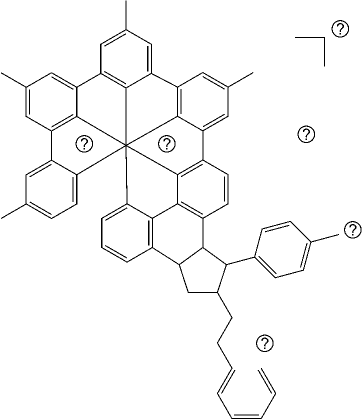 | 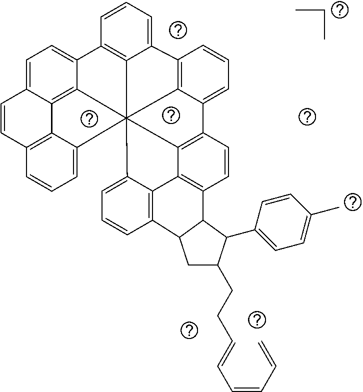 |
| | IR4-19 | IR4-20 |
| Molecular Structure | 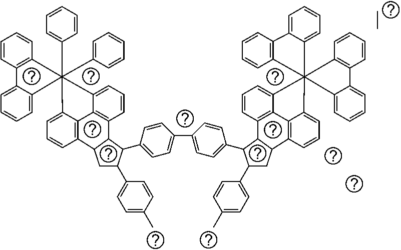 | 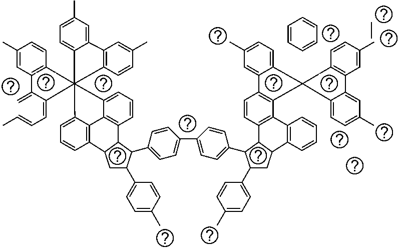 |

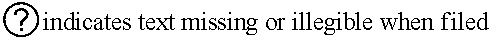

The compounds listed in Table 5 below are Er-based materials with PL emission in 700 nm to 1100 nm.

TABLE 5

| | IR5-1 | IR5-2 |
|---|---|---|
| Molecular Structure | 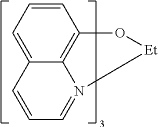 | 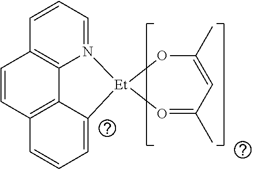 |
| | IR5-3 | IR5-4 |
| Molecular Structure | 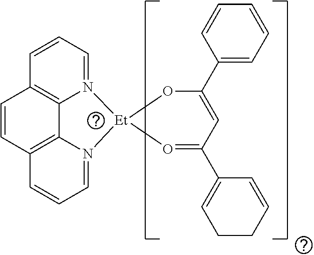 | 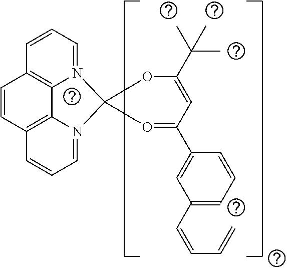 |
| | IR5-5 | IR5-6 |
| Molecular Structure | 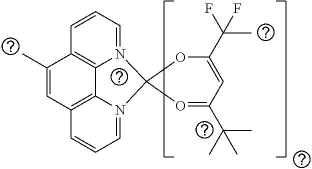 | 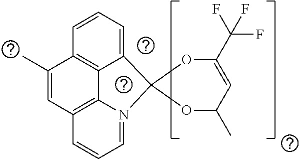 |
| | IR5-7 | IR5-8 |
| Molecular Structure | 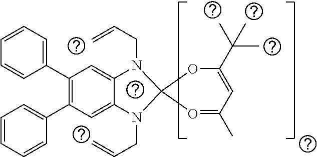 | 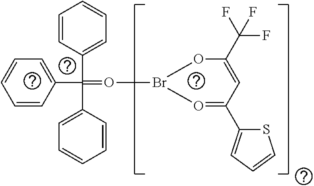 |

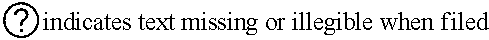

The compounds listed in Table 6 below are Nd-based materials with PL emission in 700 nm to 1100 nm.

TABLE 6

| | IR6-1 | IR6-2 |
|---|---|---|
| Molecular Structure | 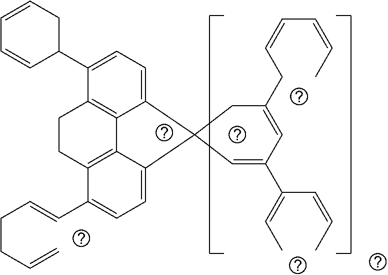 | 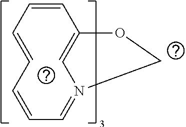 |
| | IR6-3 | IR6-4 |
| Molecular Structure | 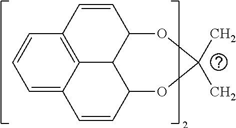 | 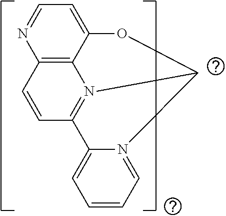 |
| | IR6-5 | |
| Molecular Structure | 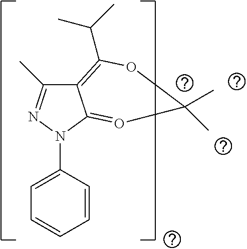 | |

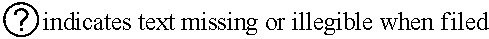

The compounds listed in Table 7 below are Yb-based materials with PL emission in 700 nm to 1100 nm.

TABLE 7

| | IR7-1 | IR7-2 |
|---|---|---|
| Molecular Structure | 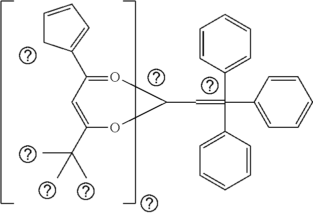 | 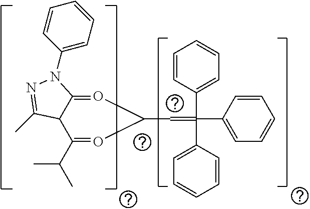 |
| | IR7-3 | IR7-4 |
| Molecular Structure | 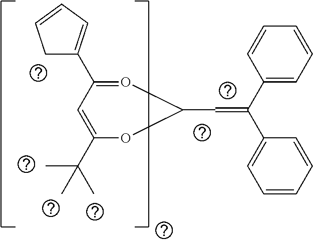 | 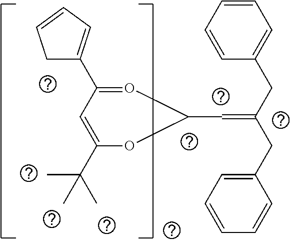 |
| | IR7-5 | IR7-6 |
| Molecular Structure | 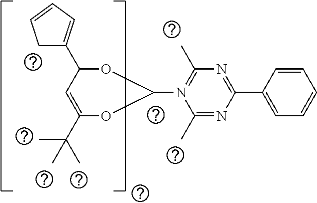 | 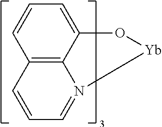 |
| | IR7-7 | IR7-8 |
| Molecular Structure | 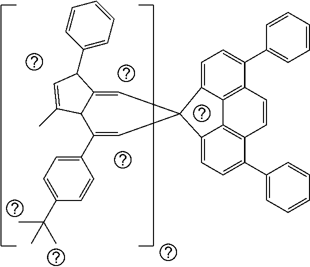 | 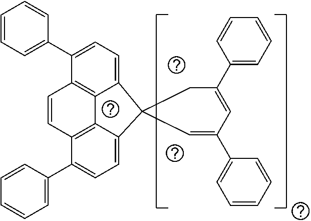 |

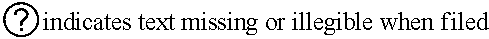

The compounds listed in Table 8 below are Ru-based materials with PL emission in 700 nm to 1100 nm.

TABLE 8

| | IR8-1 | IR8-2 |
|---|---|---|
| Molecular Structure | 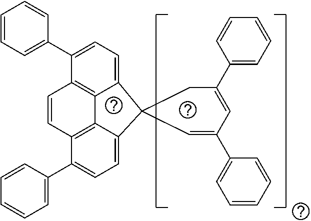 | 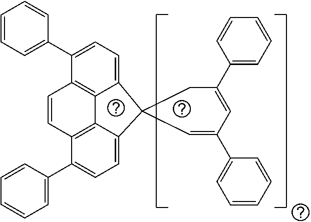 |
| | IR8-3 | |
| Molecular Structure | 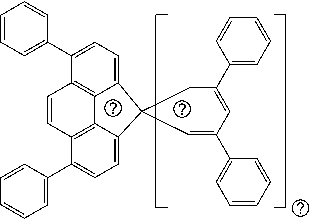 | |

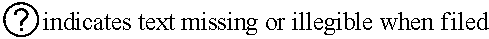

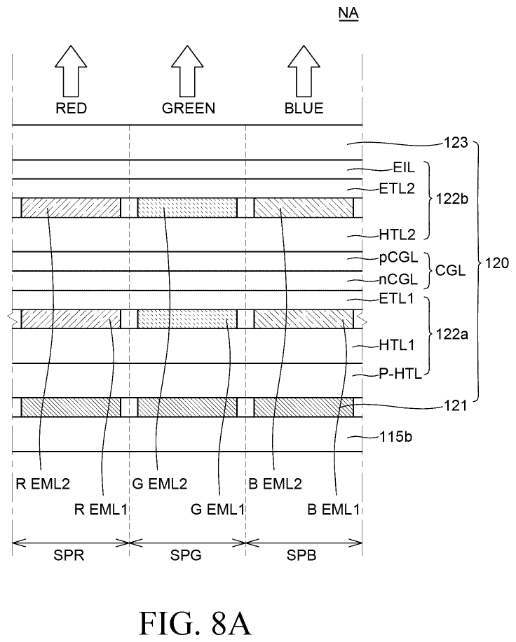

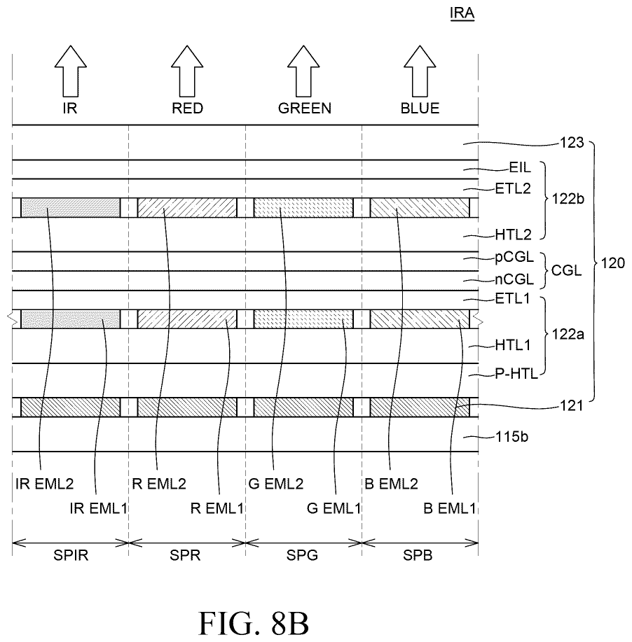

Another embodiment of the light-emitting elements 120 of the subpixels disposed in the normal area NA and the infrared ray-emitting area IRA of the display device 100 according to the embodiment of the present specification will be described with reference to FIGS. 8A and 8B.

FIG. 8A is a schematic cross-sectional view for explaining light-emitting elements of a plurality of subpixels disposed in the normal area according to the embodiment of the present specification. FIG. 8B is a schematic cross-sectional view for explaining light-emitting elements of a plurality of subpixels disposed in the infrared ray-emitting area according to the embodiment of the present specification.

With reference to FIGS. 8A and 8B, a stack structure, in which a plurality of light-emitting parts is stacked, is provided in one subpixel, in comparison with the light-emitting elements of the subpixels illustrated in FIGS. 7A and 7B. Specifically, the subpixels each include a first light-emitting part 122a and a second light-emitting part 122b.

With reference to FIG. 8A, as described with reference to FIG. 4, one unit pixel disposed in the normal area NA may include the red subpixel SPR, the green subpixel SPG, and the blue subpixel SPB. In this case, the subpixels SPR, SPG, and SPB each include the light-emitting element including the anode 121, the first light-emitting part 122a, a charge generation layer, the second light-emitting part 122b, and the cathode 123.

The first light-emitting part 122a is disposed on the anode 121. The first light-emitting part 122a may be partially identical to the light-emitting part described with reference to FIG. 7A. For example, the first light-emitting part 122a may include at least one of a hole injection layer, the first hole transport layer HTL1, a first light-emitting layer EML1, and an electron transport layer ETL1. More specifically, with reference to FIG. 8A, the first light-emitting part 122a includes a hole injection layer P-HTL, the first hole transport layer HTL1, the first light-emitting layer EML1, and a first electron transport layer ETL1.

The charge generation layer CGL is disposed between the first light-emitting part 122a and the second light-emitting part 122b. The charge generation layer CGL adjusts a charge balance of a first light-emitting layer of the first light-emitting part 122a and a second light-emitting layer of the second light-emitting part 122b. The charge generation layer may include an N-type charge generation layer N-CGL and a P-type charge generation layer P-CGL. The N-type charge generation layer N-CGL injects electrons into the first light-emitting part 122a. The N-type charge generation layer N-CGL may include an N-type dopant and an N-type host material. The P-type charge generation layer P-CGL injects positive holes into the second light-emitting part 122b. The P-type charge generation layer P-CGL has a structure disposed on the N-type charge generation layer N-CGL and joined to the N-type charge generation layer N-CGL.

The second light-emitting part 122b is disposed on the charge generation layer CGL. The second light-emitting part 122b includes a second hole transport layer HTL2, a second light-emitting layer EML2, and a second electron transport layer ETL2.

The light-emitting elements 120, which constitute the red subpixel SPR, the green subpixel SPG, and the blue subpixel SPB disposed in the normal area NA, each include the first light-emitting part 122a and the second light-emitting part 122b, and the first light-emitting part 122a and the second light-emitting part 122b include light-emitting layers configured to emit light beams with the same color. However, the present specification is not limited thereto. The first light-emitting part 122a and the second light-emitting part 122b may emit light beams with different wavelengths.

Next, with reference to FIG. 8B, as described with reference to FIG. 4, one unit pixel disposed in the infrared ray-emitting area IRA may include the red subpixel SPR, the green subpixel SPG, the blue subpixel SPB, and the infrared ray subpixel SPIR.

In this case, the subpixels SPR, SPG, SPB, and SPIR disposed in the infrared ray-emitting area IRA each include the light-emitting element including the anode 121, the first light-emitting part 122a, the charge generation layer, the second light-emitting part 122b, and the cathode 123 disposed on the second planarization layer 115b.

The light-emitting element 120 of each of the red subpixel SPR, the green subpixel SPG, and the blue subpixel SPB disposed in the infrared ray-emitting area IRA illustrated in FIG. 8B is substantially identical in structure to the light-emitting element 120 of each of the subpixels SPR, SPG, and SPB disposed in the normal area NA described above with reference to FIG. 8A. Therefore, a repeated description thereof will be omitted.

With reference to FIG. 8B, like the subpixels SPR, SPG, and SPB disposed in the normal area NA described with reference to FIG. 8A, the infrared ray subpixel SPIR disposed in the infrared ray-emitting area IRA includes the light-emitting element including the anode 121, the first light-emitting part 122a, the charge generation layer CGL, the second light-emitting part 122b, and the cathode 123.

In this case, the first light-emitting part 122a of the first light-emitting part 122a, which constitutes the light-emitting element of the infrared ray subpixel SPIR, includes a first infrared ray-emitting layer IR EML2, and the second light-emitting part 122b of the second light-emitting part 122b includes a second infrared ray-emitting layer IR EML3. The first infrared ray-emitting layer IR EML2 and the second infrared ray-emitting layer IR EML3 may emit light in the near infrared ray-emitting area with a wavelength of 700 nm to 1100 nm.

With reference to FIGS. 6 to 8B, the infrared ray subpixel SPIR disposed in the infrared ray-emitting area IRA includes the light-emitting part configured to emit light in the infrared ray-emitting area IRA. The infrared ray-emitting area IRA may emit infrared rays through the infrared ray subpixel SPIR while displaying images by emitting light in a visible light range through the red subpixel SPR, the green subpixel SPG, and the blue subpixel SPB.

Therefore, the infrared ray-emitting area IRA may serve as the transmitter of the infrared detection sensor by means of the infrared ray subpixel SPIR. The infrared rays emitted from the infrared ray-emitting area IRA may be reflected by an object disposed outside the display device, and the infrared rays may be received by the second electronic optical device 170b disposed in the second optical area OA2 to be described below.

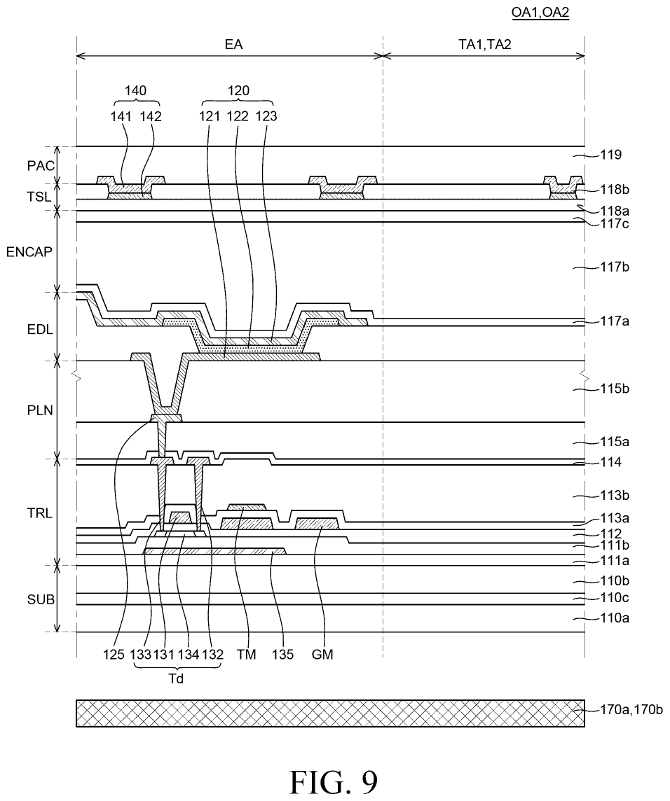

The first optical area OA1 and the second optical area OA2 of the display device 100 according to the embodiment of the present specification will be more specifically described with reference to FIG. 9.

FIG. 9 is a view illustrating cross-sectional structures of the light-emitting areas and the transmissive areas of the first optical area and the second optical area according to the embodiment of the present specification.

With reference to FIG. 9, the first optical area OA1 and the second optical area OA2 each include the light-emitting area EA and the transmissive areas TA1 and TA2. Hereinafter, for convenience of description, the first optical area OA1 and the second optical area OA2 of the display device 100 are described as one optical area OA1 or OA2. However, the description of one optical area OA1 or OA2 may be equally applied to the first optical area OA1 and the second optical area OA2.

The light-emitting area EA and the transmissive areas TA1 and TA2 of the optical areas OA1 and OA2 may each basically include the substrate SUB, the transistor layer TRL, the planarization layer PLN, the light-emitting element layer EDL, the encapsulation layer ENCAP, the touch detection layer TSL, and the protective layer PAC.

The substrate SUB, the transistor layer TRL, the planarization layer PLN, the light-emitting element layer EDL, the encapsulation layer ENCAP, the touch detection layer TSL, and the protective layer PAC included in the optical areas OA1 and OA2 are substantially identical to the constituent element having the same reference numerals and disposed in the normal area NA of the display panel DP described above with reference to FIG. 6. Therefore, a repeated description thereof will be omitted. In addition, because the light-emitting area EA of each of the optical areas OA1 and OA2 is substantially identical in structure to the normal area NA of the display panel DP, a repeated description thereof will be omitted.

Hereinafter, the transmissive areas TA1 and TA2 disposed in the optical areas OA1 and OA2 will be described.

The substrate SUB and various types of insulation films 111a, 111b, 112, 113a, 113b, 114, 115a, 115b, 117a, 117b, 117c, and PAC disposed in the light-emitting areas EA of the optical areas OA1 and OA2 may be equally disposed in the transmissive areas TA1 and TA2 of the optical areas OA1 and OA2.

However, because the transmissive areas TA1 and TA2 in the optical areas OA1 and OA2 overlap with the electronic optical devices 170a and 170b, the transmittance of the transmissive areas TA1 and TA2, which allows the electronic optical devices 170a and 170b to normally operate, needs to be ensured. Therefore, other than the insulating material disposed in the light-emitting areas EA of the optical areas OA1 and OA2, a material layer having electrical or opaque properties may not be disposed in the transmissive areas TA1 and TA2 of the optical areas OA1 and OA2.

For example, the metallic material layers 135, 131, GM, TM, 132, 133, and 125 and the active layer 134 related to the transistor are not disposed in the transmissive areas TA1 and TA2. The anode 121 included in the light-emitting element 120 may not be disposed in the transmissive areas TA1 and TA2. The cathode 123 may not be disposed in an area, except for a partial area adjacent to the light-emitting area EA in the transmissive area TA. The light-emitting part 122 may or may not be disposed in the transmissive area TA. The touch sensor metal 141 and the bridge metal 142 included in the touch sensor may not be disposed in the transmissive areas TA1 and TA2.

Because the transmissive areas TA1 and TA2 in the optical areas OA1 and OA2 overlap with the electronic optical devices 170a and 170b, the transmittance of the transmissive areas TA1 and TA2, which allows the electronic optical devices 170a and 170b to normally operate, needs to be ensured. According to the embodiment of the present specification, the cathode 123 is not disposed in the transmissive areas TA1 and TA2 in order to ensure the transmittance of the transmissive areas TA1 and TA2.

In order to implement this configuration, the anti-deposition layer (not illustrated) may be made of an organic material may be disposed on the planarization layer 115b and the light-emitting part 122 of the transmissive areas TA1 and TA2. The anti-deposition layer serves to suppress deposition of the cathode 123. During a process of forming the cathode electrode, a cathode electrode material is not deposited on the anti-deposition layer, such that the cathode electrode may be selectively formed on the substrate SUB.

In addition, the metallic material layers 135, 131, GM, TM, 132, 133, and 125 and the active layer 134 related to the transistor are not disposed in the transmissive areas TA1 and TA2. In addition, the anode 121 included in the light-emitting element 120 may also not be disposed in the transmissive areas TA1 and TA2. In addition, the touch line may not be disposed in the transmissive areas TA1 and TA2.

That is, because the transmissive areas TA1 and TA2 of the optical areas OA1 and OA2 overlap with the electronic optical devices 170a and 170b, the opaque constituent elements, such as the metal electrode, are not disposed in the transmissive areas TA1 and TA2 for normal operations of the electronic optical devices 170a and 170b, which may improve the transmittance of the transmissive areas TA1 and TA2.

In addition, because the constituent elements, such as the metal electrode, are not disposed in the transmissive areas TA1 and TA2 of the optical areas OA1 and OA2, the transmissive areas TA1 and TA2 of the optical areas OA1 and OA2 may be configured only by flat layers.

Meanwhile, in case that the display device 100 is a UDC model or a UDIR model, the UV reliability may deteriorate when the cathode 123 is removed to ensure the transmittance of the transmissive areas TA1 and TA2. That is, a pixel shrinkage defect of the light-emitting part may occur because of outgassing of an organic material caused by the transmission of UV rays.

Therefore, according to the embodiment of the present specification, it is possible to suppress the occurrence of outgassing of an organic material, which is caused by the transmission of UV rays, by reducing a volume of the organic material by removing a part of the organic material in the transmissive areas TA1 and TA2.

Meanwhile, the first optical area OA1 and the second optical area OA2 of the display device 100 have been described as one optical area OA1 or OA2 with reference to FIG. 9, for convenience of description. However, the cross-sectional structures of the transmissive areas TA1 and TA2 in the first optical area OA1 and the second optical area OA2 may be different from each other depending on the types of the electronic optical devices 170a and 170b disposed in the first optical area OA1 and the second optical area OA2.

For example, as described above with reference to FIG. 4, in case that the first electronic optical device 170a, which overlaps the first optical area OA1, is a camera and the second electronic optical device 170b, which overlaps the second optical area OA2, is an infrared detection sensor, the camera may require a larger light amount than the infrared detection sensor. Therefore, the first transmissive area TA1 of the first optical area OA1 needs to have higher transmittance than the second transmissive area TA2 of the second optical area OA2.

To this end, in the display panel DP of the display device 100 according to the present specification, the first transmissive area TA1 in the first optical area OA1 may have a transmittance improvement structure (TIS). For example, the first transmissive area TA1 in the first optical area OA1 may have, as the transmittance improvement structure (TIS), a structure in which the plurality of inorganic layers is removed and the first planarization layer 115a is recessed downward.

The display device according to the embodiment of the present specification provides a display device in which the electronic optical devices, such as the camera and the infrared detection sensor, are disposed in the display area. An infrared detection sensor in the related art includes a transmitting device disposed below a display panel and configured to emit infrared rays to the outside of the display panel, and a receiving device configured to receive and detect the infrared rays reflected by a target object. In case that the transmitting device and the receiving device of the infrared detection sensor are disposed in a display area, a light-emitting area is not disposed, and an optical area including a transmissive area and having high transmittance needs to be disposed. However, the optical area including the transmissive area has the light-emitting area with a low density, which decreases resolution. For this reason, there is a problem in that resolution of a part of the display area of the display panel decreases.

In the display device according to the embodiment of the present specification, the infrared transmitter, which constitutes the infrared detection sensor in the related art, is substituted with the infrared ray-emitting area formed in the display area and including the subpixel configured to emit infrared rays, such that the separate infrared transmitting device, which constitutes the infrared detection sensor, may be removed. The infrared transmitter is disposed below the display panel and positioned in the display area in the display panel, which may reduce an area of the optical area including the transmissive area occupied by the infrared transmitter. Therefore, it is possible to compensate for the deterioration in resolution caused by the transmissive area.

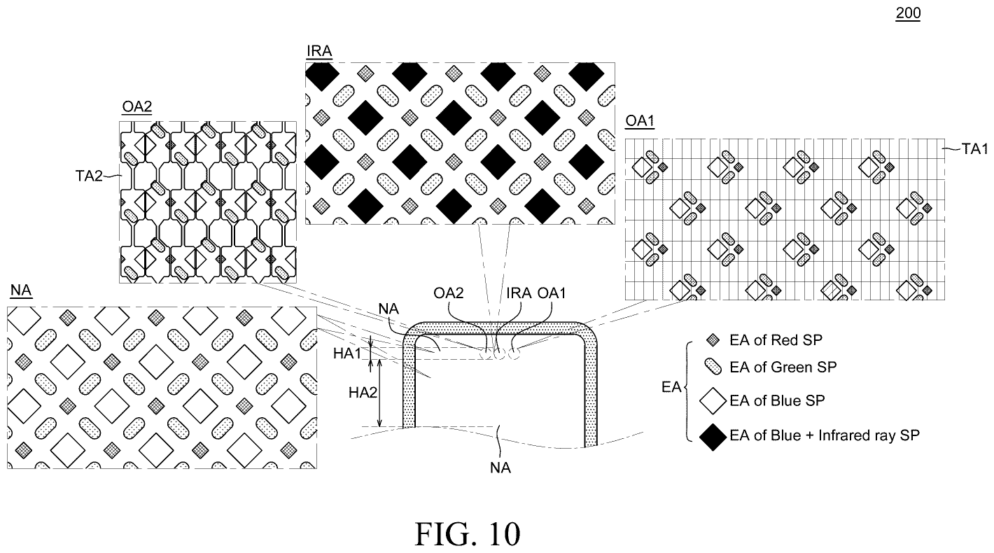

FIG. 10 is a schematic top plan view illustrating an example in which subpixels are disposed in a display area of a display device according to another embodiment of the present specification.

With reference to FIG. 10, a display device 200 according to another embodiment of the present specification is substantially identical to the display device 100 illustrated in FIG. 4, except that structures of the subpixels in the infrared ray-emitting area IRA are different. Therefore, repeated descriptions of the identical components will be omitted.

With reference to FIG. 10, the plurality of subpixels SP may be disposed in the normal area NA, the infrared ray-emitting area IRA, the first optical area OA1, and the second optical area OA2 included in the display area DA. For example, the plurality of subpixels SP may include the red subpixel Red SP configured to emit red light, the green subpixel Green SP configured to emit green light, and the blue subpixel Blue SP configured to emit blue light.

Specifically, the normal area NA, the first optical area OA1, and the second optical area OA2 may each include the light-emitting area EA for the red subpixel Red SP, the light-emitting area EA for the green subpixel Green SP, and the light-emitting area EA for the blue subpixel Blue SP.

However, in comparison with the normal area NA, the infrared ray-emitting area IRA includes a blue-infrared ray subpixel (Blue+Infrared lay SP) configured to simultaneously emit blue light and infrared rays instead of the blue subpixel Blue SP. That is, the infrared ray-emitting area IRA may include the light-emitting area EA of the red subpixel Red SP, the light-emitting area EA of the green subpixel Green SP, and the light-emitting area EA of the blue-infrared ray subpixel (Blue+Infrared lay SP). Because the blue-infrared ray subpixel (Blue+Infrared lay SP) simultaneously emits blue visible light and infrared rays, the infrared ray-emitting area IRA may serve as the transmitter of the infrared sensor device while displaying images.

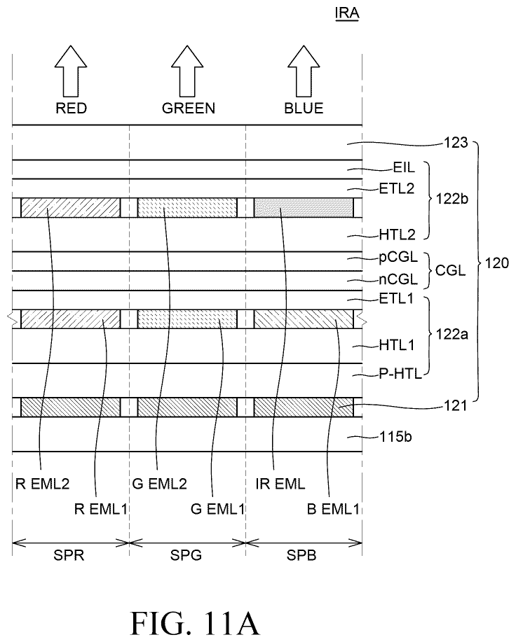

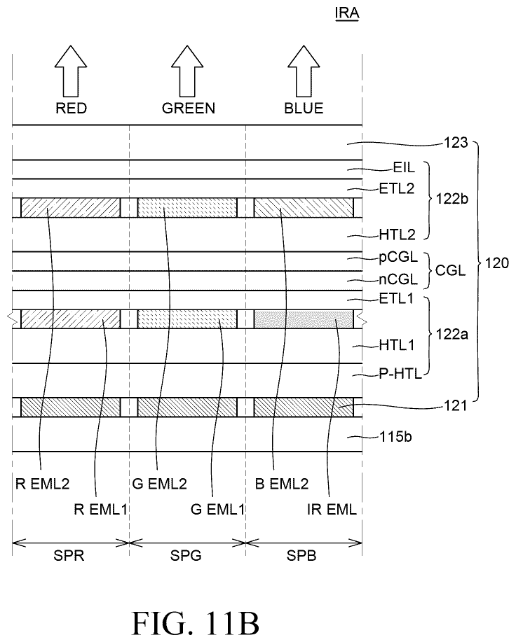

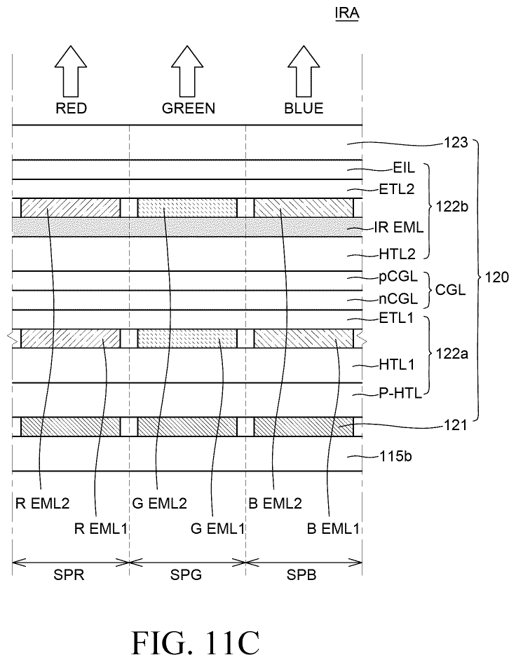

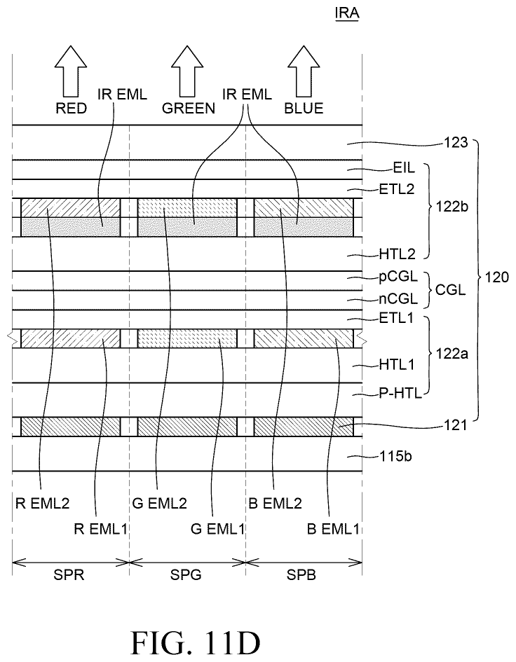

Hereinafter, with reference to FIGS. 11A to 11D, the light-emitting elements 120 of the subpixels disposed in the infrared ray-emitting area IRA of the display device 200 according to another embodiment of the present specification will be more specifically described.

The light-emitting elements of the subpixels of the display device 200 according to another embodiment of the present specification has a stack structure in which the plurality of light-emitting parts is stacked. Specifically, the subpixels each include the first light-emitting part 122a and the second light-emitting part 122b. The structure of the light-emitting element of the subpixel disposed in one unit pixel disposed in the normal area NA is substantially identical to the structure of the light-emitting element 120 of each of the subpixels SPR, SPG, and SPB disposed in the normal area NA described above with reference to FIG. 8A. Therefore, a repeated description thereof will be omitted.

FIG. 11A is a schematic cross-sectional view for explaining a first embodiment of light-emitting elements of a plurality of subpixels disposed in an infrared ray-emitting area in a display device according to another embodiment of the present specification. FIG. 11B is a schematic cross-sectional view for explaining a second embodiment of the light-emitting elements of the plurality of subpixels disposed in the infrared ray-emitting area in the display device according to another embodiment of the present specification. FIG. 11C is a schematic cross-sectional view for explaining a third embodiment of the light-emitting elements of the plurality of subpixels disposed in the infrared ray-emitting area in the display device according to another embodiment of the present specification. FIG. 11D is a schematic cross-sectional view for explaining a fourth embodiment of the light-emitting elements of the plurality of subpixels disposed in the infrared ray-emitting area in the display device according to another embodiment of the present specification.

First, with reference to FIGS. 10 and 11A, like the subpixels SPR, SPG, and SPB disposed in the normal area NA, the red subpixel SPR and the blue subpixel SPB each include the light-emitting element 120 including the anode 121, the first light-emitting part 122a, the charge generation layer CGL, the second light-emitting part 122b, and the cathode 123. In this case, the light-emitting element 120, which constitutes the red subpixel SPR, includes the first light-emitting part 122a including a first red light-emitting layer R EML1, and the second light-emitting part 122b including a second red light-emitting layer R EML2. In addition, the light-emitting element 120, which constitutes the green subpixel SPG, includes the first light-emitting part 122a including a first green light-emitting layer G EML1, and the second light-emitting part 122b including a second green light-emitting layer G EML2.

However, the light-emitting element 120, which constitutes the blue-infrared ray subpixel SPB, includes the first light-emitting part 122a including a blue light-emitting layer B EML1, and the second light-emitting part 122b including the infrared ray-emitting layer IR EML. Therefore, the blue subpixel SPB disposed in the infrared ray-emitting area IRA may simultaneously emit blue visible light and infrared rays.

Meanwhile, with reference to FIG. 11B, the light-emitting element, which constitutes the blue-infrared ray subpixel, includes the first light-emitting part 122a including the infrared ray-emitting layer IR EML, and the second light-emitting part 122b including a blue light-emitting layer B EML2. In comparison with FIG. 11A, in FIG. 11B, the infrared ray-emitting layer IR EML and the blue light-emitting layer B EML2 disposed in the blue-infrared ray subpixel may be stacked in the reverse order.

In FIGS. 10 to 11B, the structure has been described in which the subpixel, which emits blue light among the subpixels disposed in the infrared ray-emitting area IRA, simultaneously emits infrared rays. However, the subpixel, which emits red light, or the subpixel, which emits green light, may be structured to simultaneously emit infrared rays. For example, the infrared ray-emitting area IRA may include the red subpixel Red SP, the blue subpixel Blue SP, and a green-infrared ray subpixel (Green+Infrared lay SP).

Meanwhile, in case that the infrared ray-emitting layer IR EML is disposed in the subpixel configured to emit red light, the infrared ray-emitting layer IR EML may emit light in the near infrared ray-emitting area with a wavelength of 750 nm or more or a wavelength of 750 nm to 900 nm. In general, the red light-emitting layer of the red subpixel emits light with a wavelength of 600 nm to 700 nm. This is because wavelength interference with red light may occur in case that the infrared ray-emitting layer IR EML, which is disposed to overlap with the red light-emitting layer, emit light with a wavelength of less than 750 nm.

In the display device illustrated in FIGS. 10 to 11B, the subpixel, which emits only the infrared rays, is not disposed in the infrared ray-emitting area IRA, and the stack structure including the plurality of light-emitting parts in the subpixel configured to emit visible light may be used to simultaneously emit infrared rays, such that the process of displaying images and the process of emitting infrared rays may be simultaneously performed. The subpixel, which emits only the infrared rays, is not disposed in the infrared ray-emitting area IRA, such that the resolution of the infrared ray-emitting area IRA may be improved.

Next, with reference to FIG. 11C, like the subpixels SPR, SPG, and SPB disposed in the normal area NA, the red subpixel SPR, the green subpixel SPG, and the blue subpixel SPB each include the light-emitting element 120 including the anode 121, the first light-emitting part 122a, the charge generation layer CGL, the second light-emitting part 122b, and the cathode 123. In this case, like the subpixels SPR, SPG, and SPB disposed in the normal area NA described with reference to FIG. 8A, the red subpixel SPR, the green subpixel SPG, and the blue subpixel SPB may each include the first light-emitting layer EML1 and the second light-emitting layer EML2 configured to emit light with the same color and included in the first light-emitting part 122a and the second light-emitting part 122b. For example, the red subpixel SPR includes the first red light-emitting layer R EML1 included in the first light-emitting part 122a, and the second red light-emitting layer R EML2 included in the second light-emitting part 122b.

However, in the third embodiment of the light-emitting elements of the plurality of subpixels disposed in the infrared ray-emitting area illustrated in FIG. 11C, the infrared ray-emitting layer IR EML is further disposed, as a common layer, in the red subpixel SPR, the green subpixel SPG, and the blue subpixel SPB. Specifically, with reference to FIG. 11C, the second light-emitting part 122b of each of the red subpixel SPR, the green subpixel SPG, and the blue subpixel SPB includes the infrared ray-emitting layer IR EML disposed below the second light-emitting layer EML2. In this case, the infrared ray-emitting layer IR EML may be formed, as a common layer, i.e., a single layer, in the red subpixel SPR, the green subpixel SPG, and the blue subpixel SPB. Therefore, the subpixel, which emits only the infrared rays, is not disposed in the infrared ray-emitting area IRA, and the stack structure including the plurality of light-emitting parts in the subpixel configured to emit visible light may be used to simultaneously emit infrared rays, such that the process of displaying images and the process of emitting infrared rays may be simultaneously performed.

Meanwhile, the infrared ray-emitting layer IR EML, as a common layer, is disposed below the second light-emitting layer EML2. The infrared ray-emitting layer IR EML has a lower threshold voltage than the second light-emitting layer EML2 configured to emit visible rays. Therefore, even though the infrared ray-emitting layer IR EML is further disposed as a common layer, a rapid increase in voltage of the light-emitting element 120 may not occur.

Meanwhile, FIG. 11C illustrates the structure in which the infrared ray-emitting layer IR EML, as a common layer, is formed in the second light-emitting part 122b. However, the infrared ray-emitting layer IR EML may be disposed in the first light-emitting part 122a. For example, the infrared ray-emitting layer IR EML may be disposed, as a common layer, between the first hole transport layer HTL1 of the first light-emitting part 122a and the first light-emitting layer. Furthermore, the infrared ray-emitting layers IR EML may be respectively disposed in the first light-emitting part 122a and the second light-emitting part 122b.

Next, with reference to FIG. 11D, the light-emitting elements, which constitute the red subpixel SPR, the green subpixel SPG, and the blue subpixel SPB, each further include the infrared ray-emitting layer IR EML in the second light-emitting part 122b. In comparison with FIG. 11C, the infrared ray-emitting layers IR EML of the light-emitting elements according to the fourth embodiment in FIG. 11D are independently formed by being separated for each of the subpixels instead of a common layer.

In FIG. 11D, the infrared ray-emitting layer IR EML may also be formed during the process of forming the second light-emitting layer EML2 of each of the subpixels. More specifically, in general, in case that the light-emitting layer is deposited by using a fine metal mask (FMM), the light-emitting layer is deposited by sequentially disposing the fine metal masks for the respective subpixels. For this reason, in case that the subpixels are configured as three types of subpixels such as red, green, and blue subpixels, three deposition processes are required to form the light-emitting layers of the subpixels. In this case, in order to form a separate subpixel configured to emit infrared rays, the process needs to be performed by using an additional fine metal mask. However, in the fourth embodiment in FIG. 11D, during the process of forming the second light-emitting layer EML2 in one subpixel, the infrared ray-emitting layer IR EML is formed first, and then the second light-emitting layer EML2 is formed, such that the infrared ray-emitting layer IR EML may be formed without introducing a separate mask, which makes the process advantageous.

Meanwhile, FIG. 11D illustrates the structure in which the infrared ray-emitting layer IR EML is formed only in the second light-emitting part 122b. However, the infrared ray-emitting layer IR EML may be disposed only in the first light-emitting part 122a, or the infrared ray-emitting layers IR EML may be respectively disposed in the first light-emitting part 122a and the second light-emitting part 122b.

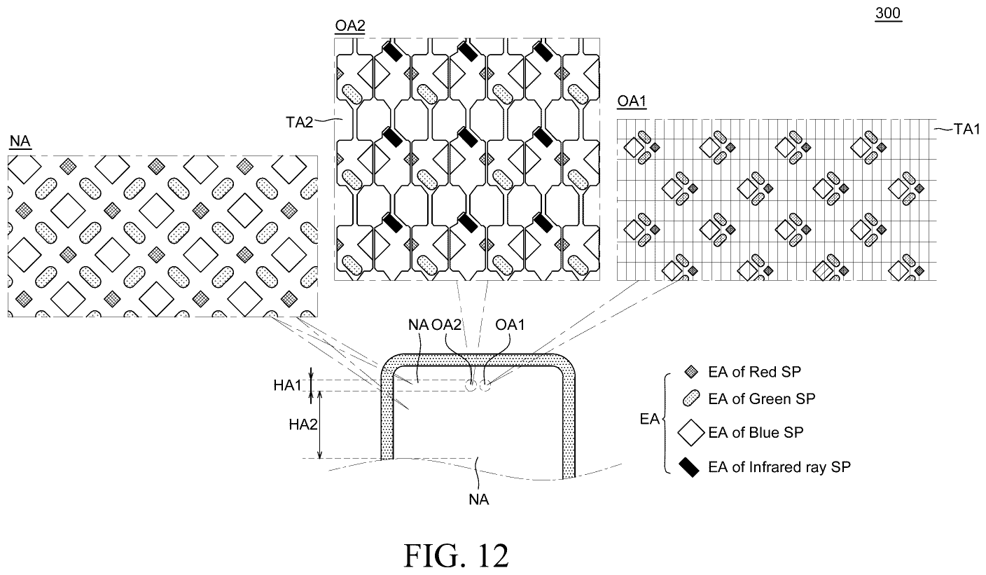

FIG. 12 is a schematic top plan view illustrating an example in which subpixels are disposed in a display area of a display device according to still another embodiment of the present specification.

With reference to FIG. 12, a display device 300 according to still another embodiment of the present specification is substantially identical to the display device 100 illustrated in FIG. 4, except that the infrared ray-emitting area IRA is excluded, and the structures of the subpixels of the second optical area are different. Therefore, repeated descriptions of the identical components will be omitted.

With reference to FIG. 12, in the display device 100 according to the embodiments of the present specification, the display area DA may include the first optical area OA1, the second optical area OA2, and the normal area NA.

In this case, the plurality of subpixels SP may be disposed in the normal area NA, the first optical area OA1, and the second optical area OA2 included in the display area DA. For example, the plurality of subpixels SP may include the red subpixel Red SP configured to emit red light, the green subpixel Green SP configured to emit green light, and the blue subpixel Blue SP configured to emit blue light.

Specifically, as described with reference to FIG. 4, the normal area NA, the first optical area OA1, and the second optical area OA2 may each include the light-emitting area EA for the red subpixel Red SP, the light-emitting area EA for the green subpixel Green SP, and the light-emitting area EA for the blue subpixel Blue SP.

However, the second optical area OA2 further includes the infrared ray subpixel Infrared ray SP capable of emitting infrared rays in addition to the red subpixel Red SP, the green subpixel Green SP, and the blue subpixel Blue SP. The infrared ray subpixel Infrared ray SP is a pixel configured to emit light in the near infrared ray-emitting area IRA with a wavelength of 700 nm to 1100 nm.

In comparison with the display device 100 illustrated in FIG. 4 including the separate infrared ray-emitting area IRA, the infrared ray subpixel Infrared ray SP is formed in the second optical area OA2 in the display device 300 illustrated in FIG. 12. For example, unlike the configuration in which the first optical area OA1 is disposed in the unit pixel together with the first transmissive area TA1 so that one red subpixel Red SP, two green subpixels Green SP, and one blue subpixel Blue SP are included, the second optical area OA2 may include one red subpixel Red SP, one green subpixel Green SP, one blue subpixel Blue SP, and one infrared ray subpixel Infrared ray SP together with the second transmissive area TA2.

In the display device 300 illustrated in FIG. 12, the separate infrared ray-emitting area IRA is not formed, and the subpixel, which emits infrared rays, is disposed in the second optical area in which the infrared detection device is disposed, such that the infrared detection sensor may be implemented without a separate infrared transmitting device. The infrared transmitting device of the infrared detection device disposed in the second optical area is excluded, such that a size of the second optical area may be reduced so that only the infrared receiving device corresponds to the second optical area. Therefore, an area of the optical area including the transmissive area occupied to transmit infrared rays may be reduced, and the deterioration in resolution caused by the transmissive area may be compensated.

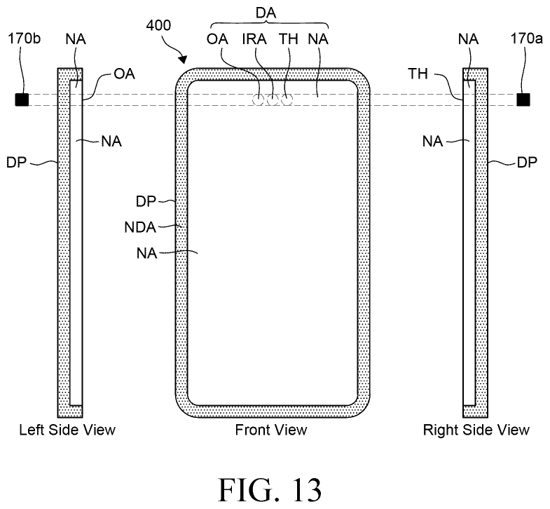

FIG. 13 is a schematic top plan view of a display device according to yet another embodiment of the present specification.

With reference to FIG. 13, the display device 300 according to yet another embodiment of the present specification is substantially identical to the display device 100 illustrated in FIG. 4, except that a camera area is formed instead of the first optical area. Therefore, repeated descriptions of the identical components will be omitted.

With reference to FIG. 13, in the display device 100 according to yet another embodiment of the present specification, the display area DA may include a camera area CA, an optical area OA, the normal area NA, and the infrared ray-emitting area IRA. The camera area CA is an area that overlaps a camera, and the optical area OA is an area that overlaps an infrared sensor device. Because the optical area OA in the display device 300 illustrated in FIG. 13 is substantially identical to the second optical area OA2 of the display device 100 illustrated in FIG. 4, a repeated description thereof will be omitted.

The camera area CA may be an area that overlaps the camera, i.e., an area in which the touch electrode and the light-emitting element are not disposed. The camera area CA may include a through-hole TH. The through-hole TH may be a hole formed through the substrate SUB, the transistor layer TRL, the light-emitting element layer EDL, and the touch detection layer TSL. In addition, the through-hole TH may not be formed through a cover window. The through-hole TH may be formed to correspond to the camera.

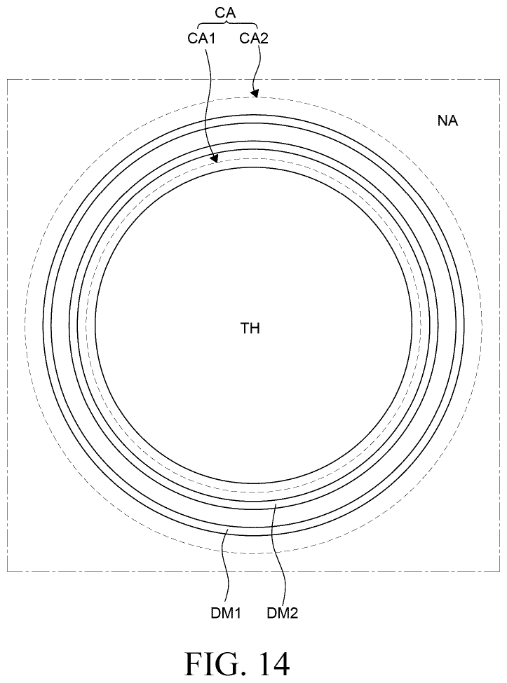

FIG. 14 is a schematic top plan view for explaining a camera area of a display device according to still yet another embodiment of the present specification.

The camera area CA includes a first area CA1, and a second area CA2 between the first area CA1 and the normal area NA. The first area CA1 includes the through-hole TH. A plurality of dams DM1 and DM2 and a plurality of patterns are disposed in the second area CA2 and surround the through-hole TH. The first area CA1 may refer to the through-hole TH and a peripheral area that surrounds the through-hole TH. The second area CA2 may refer to an area that surrounds the first area CA1.

The through-hole TH is formed in the camera area CA. Specifically, the through-hole TH may be positioned in a central portion of the first area CA1. The through-hole TH may be physically formed through the encapsulation layer ENCAP from the substrate SUB. The through-hole TH may be formed to correspond to the camera. However, the present specification is not limited thereto. An optical sensor may be disposed in the through-hole TH. The light may be easily transmitted by the upper portion of the camera or optical sensor through the through-hole TH.

The plurality of dams DM1 and DM2 is disposed in the second area CA2 and surrounds the through-hole TH. The plurality of dams DM1 and DM2 may be disposed between the through-hole TH and a display area AA. The plurality of dams DM1 and DM2 may inhibit the encapsulation layer ENCAP from overflowing into the through-hole TH. The plurality of dams DM1 and DM2 may include a first dam DM1 and a second dam DM2. Meanwhile, the drawing illustrates that one first dam DM1 and one second dam DM2 are disposed. However, the present specification is not limited thereto.

The first dam DM1 may be formed in a shape of a closed loop that surrounds an outer periphery of the through-hole TH. The first dam DM1 is disposed to be closer to the normal area NA than the second dam DM2 to the normal area NA. That is, the first dam DM1 may primarily inhibit the encapsulation layer ENCAP from overflowing. Therefore, the encapsulation layer ENCAP may be formed from the normal area NA to the inside of the first dam DM1 by the first dam DM1. The second dam DM2 may be formed in a shape of a closed loop that surrounds the outer periphery of the through-hole TH. The second dam DM2 is disposed to be closer to the through-hole TH than the first dam DM1 to the through-hole TH.

The plurality of patterns may be disposed in the second area CA2 and surrounds the through-hole TH. The plurality of patterns may each be formed in a shape of a closed loop that surrounds the outer periphery of the through-hole TH. The plurality of patterns may inhibit moisture from penetrating into the normal area NA through the light-emitting element layer EDL. That is, the light-emitting element layer EDL, which is vulnerable to the penetration of moisture, may have a disconnection structure by the plurality of patterns. Specifically, a top surface of a first sub-pattern of each of the plurality of patterns may have a smaller width of a bottom surface of a second sub-pattern. Therefore, the light-emitting element layer EDL disposed above the plurality of patterns may be disconnected by the plurality of patterns without being continuously formed. Therefore, even though moisture penetrates through the light-emitting element layer EDL, the disconnected structure of the light-emitting element layer EDL may inhibit the penetrating moisture from moving to the display area AA.

The exemplary embodiments of the present disclosure can also be described as follows:

According to an aspect of the present disclosure, there is provided a display device. The display device includes a display panel comprising a display area including a plurality of subpixels, and a non-display area configured to surround the display area, the display area comprising a first optical area including a first transmissive area, a second optical area including a second transmissive area, and a normal area including a light-emitting area; a first optical device disposed below the display panel and configured to overlap with the first optical area; and a second optical device disposed below the display panel and configured to overlap with the second optical area. The display panel is disposed in at least a partial area in the display area and comprises an infrared ray subpixel including an infrared ray-emitting layer.

The display panel may be disposed adjacent to the first optical area or the second optical area and may further comprise an infrared ray-emitting area including the infrared ray subpixel.

The first optical area may comprise the first transmissive area and a first light-emitting area including the plurality of subpixels. The second optical area may comprise the second transmissive area and a second light-emitting area including the plurality of subpixels. Transmittance of the first optical area may be higher than transmittance of the second optical area.

The second optical device may be an infrared receiving device configured to receive infrared rays emitted from the infrared ray subpixel.

The normal area may comprise a red subpixel, a green subpixel, and a blue subpixel. The infrared ray-emitting area may further comprise a red subpixel, a green subpixel, and a blue subpixel.

At least one of the red subpixel, the green subpixel, and the blue subpixel of the infrared ray-emitting area may comprise the infrared ray-emitting layer.

The red subpixel, the green subpixel, and the blue subpixel of the infrared ray-emitting area each may comprise a light-emitting element comprising an anode, a first light-emitting part including a first light-emitting layer, a second light-emitting part including a second light-emitting layer, a cathode, and a charge generation layer disposed between the first light-emitting part and the second light-emitting part. Any one of the first light-emitting layer and the second light-emitting layer of at least one of the red subpixel, the green subpixel, and the blue subpixel may be the infrared ray-emitting layer.

Any one of the first light-emitting layer and the second light-emitting layer of the red subpixel may be the infrared ray-emitting layer. The infrared ray-emitting layer may emit infrared rays with a wavelength of 750 nm to 900 nm.

The red subpixel, the green subpixel, and the blue subpixel of the infrared ray-emitting area each may comprise a light-emitting element comprising an anode, a first light-emitting part including a first light-emitting layer, a second light-emitting part including a second light-emitting layer, a cathode, and a charge generation layer disposed between the first light-emitting part and the second light-emitting part. The infrared ray-emitting layer may be disposed below the first light-emitting layer or the second light-emitting layer of each of the red subpixel, the green subpixel, and the blue subpixel.

The infrared ray-emitting layer may be disposed, as a common layer, continuously in the red subpixel, the green subpixel, and the blue subpixel.

The second optical area may comprise the infrared ray subpixel. The second optical device may be an infrared receiving device configured to receive infrared rays emitted from the infrared ray subpixel.

The second optical area may comprise the second transmissive area and a second light-emitting area comprising a red subpixel, a green subpixel, a blue subpixel, and the infrared ray subpixel.

The first optical area may comprise a through-hole from which an organic layer and an inorganic layer constituting the display panel are removed.

The first optical device is a camera device.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display panel comprising a display area including a plurality of subpixels, and a non-display area surrounding the display area, the display area comprising a first optical area including a first transmissive area, a second optical area including a second transmissive area, and a normal area including a light-emitting area;
a first optical device disposed below the display panel and overlapping with the first optical area; and
a second optical device disposed below the display panel and overlapping with the second optical area,
wherein the display panel includes an infrared ray subpixel including an infrared ray-emitting layer, the infrared ray subpixel being disposed at least partially in the display area.

2. The display device of claim 1, wherein the display panel further comprises an infrared ray-emitting area including the infrared ray subpixel, and the an infrared ray-emitting area is disposed adjacent to the first optical area or the second optical area.

3. The display device of claim 2, wherein the first optical area comprises the first transmissive area and a first light-emitting area including a first group of subpixels of the plurality of subpixels,
wherein the second optical area comprises the second transmissive area and a second light-emitting area including a second group of subpixels of the plurality of subpixels, and
wherein transmittance of the first optical area is higher than transmittance of the second optical area.

4. The display device of claim 3, wherein the second optical device is an infrared receiving device configured to receive infrared rays emitted from the infrared ray subpixel.

5. The display device of claim 2, wherein the normal area comprises a red subpixel, a green subpixel, and a blue subpixel, and
wherein the infrared ray-emitting area further comprises a red subpixel, a green subpixel, and a blue subpixel.

6. The display device of claim 5, wherein at least one of the red subpixel, the green subpixel, or the blue subpixel of the infrared ray-emitting area comprises the infrared ray-emitting layer.

7. The display device of claim 6, wherein the red subpixel, the green subpixel, and the blue subpixel of the infrared ray-emitting area each comprises a light-emitting element comprising an anode, a first light-emitting part including a first light-emitting layer, a second light-emitting part including a second light-emitting layer, a cathode, and a charge generation layer disposed between the first light-emitting part and the second light-emitting part, and
wherein any one of the first light-emitting layer and the second light-emitting layer of at least one of the red subpixel, the green subpixel, and the blue subpixel is the infrared ray-emitting layer.

8. The display device of claim 7, wherein any one of the first light-emitting layer and the second light-emitting layer of the red subpixel is the infrared ray-emitting layer, and
wherein the infrared ray-emitting layer is configured to emit infrared rays with a wavelength of 750 nm to 900 nm.

9. The display device of claim 6, wherein the red subpixel, the green subpixel, and the blue subpixel of the infrared ray-emitting area each comprises a light-emitting element comprising an anode, a first light-emitting part including a first light-emitting layer, a second light-emitting part including a second light-emitting layer, a cathode, and a charge generation layer disposed between the first light-emitting part and the second light-emitting part, and
wherein the infrared ray-emitting layer is disposed below the first light-emitting layer or the second light-emitting layer of each of the red subpixel, the green subpixel, and the blue subpixel.

10. The display device of claim 9, wherein the infrared ray-emitting layer is disposed, as a common layer, continuously in the red subpixel, the green subpixel, and the blue subpixel.

11. The display device of claim 1, wherein the second optical area comprises the infrared ray subpixel, and
wherein the second optical device is an infrared receiving device configured to receive infrared rays emitted from the infrared ray subpixel.

12. The display device of claim 11, wherein the second optical area comprises the second transmissive area and a second light-emitting area comprising a red subpixel, a green subpixel, a blue subpixel, and the infrared ray subpixel.

13. The display device of claim 1, wherein the first optical area comprises a through-hole from which an organic layer and an inorganic layer constituting the display panel are removed.

14. The display device of claim 13, wherein the first optical device is a camera device.
